(19) United States
(12) Patent Application Publication
(10) Pub. No.: US 2026/0262209 A1
(43) Pub. Date: Sep. 3, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Yoshiyuki KUROKAWA, Sagamihara (JP); Takanori MATSUZAKI, Atsugi (JP)

(21) Appl. No.: 19/157,536

(22) PCT Filed: Feb. 16, 2024
(86) PCT No.: PCT/IB2024/051464

§ 371 Date: Aug. 18, 2025

(30) Foreign Application Priority Data
Feb. 24, 2023 (JP) 2023-026953
Mar. 10, 2023 (JP) 2023-037340

(51) Int. Cl. H10B 12/00; G11C 11/405

(52) U.S. Cl. CPC H10B 12/00; G11C 11/405

(57) ABSTRACT

A semiconductor device with a novel structure is provided. A first element layer is provided with an arithmetic unit. A second element layer is provided with a memory unit. The arithmetic unit includes a first transistor in which a first semiconductor layer including a channel formation region contains silicon. The memory unit includes the first transistor and a second transistor in which a second semiconductor layer including a channel formation region contains an oxide semiconductor. The arithmetic unit includes an instruction decoding portion. The memory unit includes an instruction cache. The second element layer includes a plurality of layers each including the second transistor, and layers including the second transistors are stacked. The instruction cache is provided in a region included in the second element layer above the instruction decoding portion provided in the first element layer.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device (a memory device), a driving method thereof, and a manufacturing method thereof.

### BACKGROUND ART

A CPU (central processing unit) performs a series of processing by successively executing processing corresponding to a program (data) stored in a memory. Data necessary for the processing is also stored in the memory. Therefore, the speed at which the CPU accesses the memory or its power consumption significantly affects the CPU's arithmetic capability, power consumption, or the like.

A structure where the data on all memories can be accessed equally has broad utility but lowers the speed at which the CPU accesses the memory, resulting in decreased arithmetic capability and increased power consumption. Therefore, a structure in which memories are layered, that is, a structure in which a cache memory composed of an SRAM or the like, a main memory device composed of a DRAM or the like, an auxiliary memory device such as a flash memory or a hard disk, and the like are provided in this order from the CPU side is generally used.

The main memory device has lower access speed than the cache memory but offers larger memory capacity. The auxiliary memory device has even lower access speed than the main memory device but offers larger memory capacity. Although the CPU basically accesses the cache memory, when the desired data is not stored in the cache memory, the CPU accesses the main memory device, copies the data to the cache memory, and then accesses the data again. Furthermore, in the case where the desired data is not stored even in the main memory device, the CPU accesses the auxiliary memory, copies the data to the main memory device and the cache memory, and then accesses the data again.

In addition, a structure in which cache memories are layered, that is, a structure in which a primary cache memory (a primary cache or an L1 cache), a secondary cache memory (a secondary cache or an L2 cache), a tertiary cache memory (a tertiary cache or an L3 cache), and the like are provided in this order from the CPU side is generally used.

Patent Document 1 discloses a structure in which a memory unit using a transistor including an oxide semiconductor in a semiconductor layer is applied to a register, a cache memory, and a main memory device. A transistor including an oxide semiconductor in the semiconductor layer has a characteristic of an extremely low off-state current. Thus, when the transistor is applied to the memory unit such as the register, the cache memory, or the main memory device, stored data can be retained for a long time.

### REFERENCE

### Patent Document

[Patent Document 1] Japanese Published Patent Application No. 2015-180994.

### SUMMARY OF THE INVENTION

### Problems to be Solved by the Invention

Increasing the memory capacity of a cache memory is effective in improving arithmetic capability and reducing power consumption of an arithmetic unit such as a CPU. However, in a CPU, an arithmetic unit including a plurality of circuit units, such as an arithmetic logic unit (Integer/ALU), occupies a large portion of a finite area. Accordingly, it is not easy to secure an area to place a memory unit for increasing memory capacity of the cache memory without reducing arithmetic capability of the arithmetic unit. Therefore, it has been difficult to achieve an increase in memory capacity of the cache memory, and an improvement in arithmetic capability and a reduction in power consumption of the arithmetic unit at the same time.

Patent Document 1 discloses a structure in which a transistor including an oxide semiconductor in a semiconductor layer is applied to a register that is a memory unit in the arithmetic unit. A register that retains data accessed by the arithmetic unit is required to have access speed. In the case where the transistor including the oxide semiconductor in the semiconductor layer is applied to the register, access speed to the register might be decreased. In addition, in the case where the transistor including the oxide semiconductor in the semiconductor layer is applied to a cache memory, which is a memory unit in a layer close to the arithmetic unit, a signal transmission distance between a plurality of circuit units included in the arithmetic unit and the cache memory is increased, which might cause an increase in power consumption and a decrease in operation speed.

One object of one embodiment of the present invention is to provide a semiconductor device with a novel structure. Another object of one embodiment of the present invention is to provide a semiconductor device that is excellent in improving arithmetic capability, reducing power consumption, increasing operation speed, downsizing, or increasing memory capacity.

Note that the objects of one embodiment of the present invention are not limited to the objects listed above. The objects listed above do not preclude the presence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a first element layer and a plurality of second element layers, in which the plurality of second element layers are provided over the first element layer, an arithmetic unit is provided in the first element layer, a memory unit is provided in each of the plurality of second element layers, the arithmetic unit includes a first transistor including a first semiconductor layer containing silicon in a channel formation region, the memory unit includes a second transistor including a second semiconductor layer containing an oxide semiconductor in a channel formation region, and the memory unit has a function of a cache memory of the arithmetic unit.

One embodiment of the present invention is a semiconductor device including a first element layer and a plurality of second element layers, in which the plurality of second element layers are provided over the first element layer, an arithmetic unit is provided in the first element layer, a memory unit is provided in each of the plurality of second element layers, the arithmetic unit includes a first transistor including a first semiconductor layer containing silicon in a channel formation region, the memory unit includes a second transistor including a second semiconductor layer containing an oxide semiconductor in a channel formation region, the arithmetic unit includes an instruction decoder, the memory unit of at least one of the plurality of second element layers includes an instruction cache, and the instruction cache is provided in a region included in the second element layer above the instruction decoder provided in the first element layer.

In the semiconductor device of one embodiment of the present invention, the oxide semiconductor preferably includes at least In.

In the semiconductor device of one embodiment of the present invention, the second transistor is preferably a vertical transistor.

In the semiconductor device of one embodiment of the present invention, it is preferable that the arithmetic unit included in the first element layer and the memory unit included in each of the plurality of second element layers are electrically connected to each other via a through electrode provided in each of the plurality of second element layers.

In the semiconductor device of one embodiment of the present invention, it is preferable that the arithmetic unit included in the first element layer and the memory unit included in each of the plurality of second element layers are electrically connected to each other through a wiring layer included in the first element layer and a wiring layer included in each of the plurality of second element layers.

In the semiconductor device of one embodiment of the present invention, it is preferable that the arithmetic unit included in the first element layer includes a flip-flop, each of the plurality of second element layers includes a backup circuit electrically connected to the flip-flop, the backup circuit has a function of retaining a data signal written to the flip-flop, and a region where the backup circuit is provided overlaps with a region where the flip-flop is provided.

Note that other embodiments of the present invention are illustrated in the description of the following embodiments and the drawings.

### Effect of the Invention

One embodiment of the present invention can provide a novel semiconductor device or the like. Another embodiment of the present invention can provide a semiconductor device that is excellent in improving arithmetic capability, reducing power consumption, increasing operation speed, downsizing, or increasing memory capacity.

Note that the description of these effects does not preclude the presence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are a block diagram and a schematic diagram, respectively, illustrating a structure example of a semiconductor device.

FIG. 2A and FIG. 2B are schematic diagrams each illustrating a structure example of a semiconductor device.

FIG. 3A and FIG. 3B are schematic diagrams each illustrating a structure example of a semiconductor device.

FIG. 4A and FIG. 4B are schematic diagrams each illustrating a structure example of a semiconductor device.

FIG. 5A to FIG. 5C are a block diagram illustrating structure examples of a semiconductor device and diagrams illustrating a circuit structure example.

FIG. 6 is a timing chart showing a structure example of a semiconductor device.

FIG. 7A and FIG. 7B are schematic diagrams illustrating a structure example of a semiconductor device.

FIG. 8A to FIG. 8H are circuit diagrams illustrating structure examples of a semiconductor device.

FIG. 9 is a schematic diagram illustrating a structure example of a semiconductor device.

FIG. 10A and FIG. 10B are schematic diagrams illustrating a structure example of an arithmetic processing system.

FIG. 11A and FIG. 11B are schematic diagrams illustrating structure examples of a semiconductor device.

FIG. 12A to FIG. 12C are schematic diagrams illustrating structure examples of a semiconductor device.

FIG. 13A and FIG. 13B are schematic cross-sectional views illustrating structure examples of a semiconductor device.

FIG. 14A and FIG. 14B are schematic diagrams illustrating structure examples of a semiconductor device.

FIG. 15A and FIG. 15B are schematic diagrams illustrating structure examples of a semiconductor device.

FIG. 16 is a cross-sectional view illustrating a structure example of a semiconductor device.

FIG. 17A to FIG. 17C are cross-sectional views illustrating structure examples of a semiconductor device.

FIG. 18A is a diagram illustrating a structure example of a semiconductor device. FIG. 18B is a diagram illustrating an equivalent circuit of the semiconductor device.

FIG. 19 is a diagram illustrating a structure example of a semiconductor device.

FIG. 20A is a diagram illustrating a structure example of a semiconductor device. FIG. 20B is a diagram illustrating an equivalent circuit of a semiconductor device.

FIG. 21 is a schematic cross-sectional view illustrating a structure example of a semiconductor device.

FIG. 22A to FIG. 22C are plan views illustrating a structure example of a transistor included in a semiconductor device, and FIG. 22D is a cross-sectional view illustrating the structure example of a transistor included in a semiconductor device.

FIG. 23A is a plan view illustrating a structure example of a transistor included in a semiconductor device, and FIG. 23B is a cross-sectional view illustrating the structure example of a transistor included in a semiconductor device.

FIG. 24 is a schematic cross-sectional view illustrating a structure example of a semiconductor device.

FIG. 25A and FIG. 25B are diagrams illustrating examples of electronic components.

FIG. 26A and FIG. 26B are diagrams illustrating examples of electronic devices. FIG. 26C to FIG. 26E are diagrams illustrating an example of a large computer.

FIG. 27 is a diagram illustrating an example of space equipment.

FIG. 28 illustrates an example of a storage system applicable to a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an OFF state (also referred to as a non-conduction state or a cutoff state). Unless otherwise specified, an OFF state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### Embodiment 1

A semiconductor device of one embodiment of the present invention will be described with reference to drawings. A semiconductor device is a device that utilizes semiconductor characteristics, and is a circuit including a semiconductor element (a transistor, a diode, a photodiode, or the like) and a device including the circuit. The semiconductor device described in this embodiment has a function of an arithmetic device including a memory unit that utilizes a transistor with an extremely low off-state current.

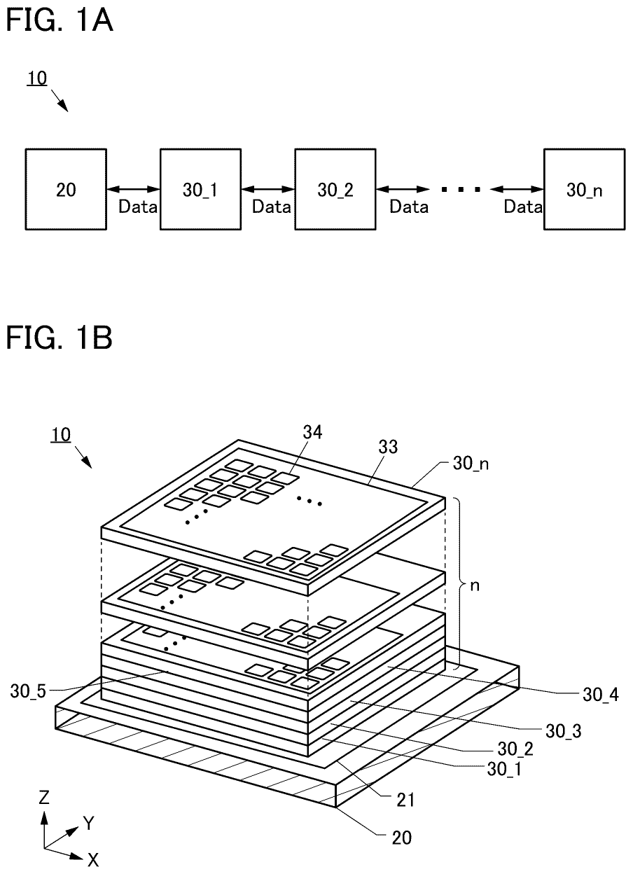

FIG. 1A is a block diagram of a semiconductor device 10 described in this embodiment. FIG. 1B is a schematic diagram of the semiconductor device 10 described in this embodiment.

FIG. 1A illustrates data (Data) between an element layer 20 and element layers 30_1 to 30_n provided over the element layer 20 illustrated in FIG. 1B. In the semiconductor device 10, the element layers 30_1 to 30_n are stacked over the element layer 20. Note that the element layer is a layer provided with a semiconductor element such as a transistor or a capacitor.

In the element layers 30_1 to 30_n of FIG. 1A and FIG. 1B, the first layer is denoted as the element layer 30_1, the second layer is denoted as the element layer 30_2, and the third layer is denoted as the element layer 30_3. An n-th layer is denoted as the element layer 30_n. Note that in this embodiment and the like, a simple term “element layer 30” is sometimes used to describe matters related to all the element layers 30_1 to 30_n or matters common to the element layers 30_1 to 30_n.

The element layer 20 includes an arithmetic unit 21. The element layer 20 includes a transistor in which a semiconductor layer including a channel formation region includes silicon (a Si transistor). The element layer 20 is an element layer provided with a semiconductor layer including a channel formation region in a silicon substrate or an element layer formed by bonding a silicon semiconductor layer including a channel formation region to a silicon substrate.

Although the description is made assuming that a substrate provided to the element layer 20 is a silicon substrate, this embodiment is not limited thereto. Note that the silicon substrate refers to a substrate including silicon as a semiconductor material, for example, a single crystal silicon substrate. Note that, without being limited to silicon, a material containing Ge (germanium), SiGe (silicon germanium), GaAs (gallium arsenide), GaAlAs (gallium aluminum arsenide), or the like may be used for the substrate.

In particular, silicon with high crystallinity, such as single crystal silicon or polycrystalline silicon, is used for the Si transistor included in the element layer 20. When the element layer 20 includes silicon with high crystallinity, high field-effect mobility can be achieved, which enables higher-speed operation. Thus, the arithmetic unit 21 included in the element layer 20 can be provided with circuit units such as an instruction decoder (Decode), a branch prediction unit (Branch Prediction), a load/store unit (Load/Store), an arithmetic logic unit (Integer/ALU), and a floating-point arithmetic unit (Floating Point).

The arithmetic unit 21 has a function of performing general-purpose processing such as execution of an operating system, control of data, various kinds of arithmetic operations, and execution of programs, like a CPU (Central Processing Unit) or a GPU (Graphics Processing Unit).

The element layers 30_1 to 30_n include transistors (OS transistors) each including an oxide semiconductor in a semiconductor layer including a channel formation region. The element layers 30_1 to 30_n including the OS transistors can be stacked over the element layer 20. In the semiconductor device 10 illustrated in FIG. 1B, the element layers 30_1 to 30_n are layered over the element layer 20. When the element layers 30_1 to 30_n are provided over the element layer 20, the transistor density per unit area can be increased.

Examples of a metal oxide applied to the OS transistors include indium oxide, gallium oxide, and zinc oxide. The metal oxide preferably contains two or three elements selected from indium, an element M, and zinc. Note that the element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium (In), tin (Sn), and zinc (Zn) (also referred to as ITZO). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO).

In addition, the metal oxide applied to the OS transistor can include two or more metal oxide layers with different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed.

Alternatively, a stacked-layer structure or the like of any one selected from indium oxide, indium gallium oxide, and IGZO, and any one selected from IAZO, IAGZO, and ITZO may be used, for example.

Note that the metal oxide applied to the OS transistor preferably has crystallinity. Examples of an oxide semiconductor having crystallinity include a CAAC (c-axis aligned crystalline)-OS and an nc (nanocrystalline)-OS. When the oxide semiconductor having crystallinity is used, a highly reliable semiconductor device can be provided.

Note that the OS transistor is preferably a vertical transistor whose source electrode and drain electrode are positioned at different levels. In the vertical transistor, a current flows in the height direction (Z direction) in a channel formation region of a semiconductor layer. In other words, a channel length direction can be regarded as having a component of the height direction (vertical direction). Thus, the above-described vertical transistor can also be referred to as a VFET (Vertical Field Effect Transistor), a vertical-channel transistor, a vertical-channel-type transistor, or a vertical transistor, for example.

In a vertical transistor, the source region, the channel formation region, and the drain region can at least partly overlap with one another in the top view, enabling a smaller occupied area (footprint). Such a transistor enables reduced channel length and increased channel width, reducing on-state resistance (increasing on-state current).

In the case where the element layers 30 including OS transistors are stacked over the element layer 20 including Si transistors, the vertical transistor can have higher memory density per unit area than a lateral transistor whose source electrode and drain electrode are positioned at the same level (also referred to as a planar structure). Since the occupied area (also referred to as a footprint) of the vertical transistor is small, it is especially effective in a structure where the element layer 30 in the upper layer has higher memory density per unit area. This structure enables a layered structure where the memory density is varied in order of proximity to the element layer 20 including the arithmetic unit 21. For example, when OS transistors in the element layer 30 close to the element layer 20 including the arithmetic unit 21 are lateral transistors and OS transistors in the element layer 30 far from the element layer 20 including the arithmetic unit 21 are vertical transistors, the layered structure where the memory density is varied in order of proximity to the element layer 20 including the arithmetic unit 21 can be obtained.

The element layers 30_1 to 30_n each include a memory unit 33 provided with a memory cell 34 including an OS transistor. Circuit structures of the memory cell 34 provided in the memory unit 33 may differ between the element layers 30_1 to 30_n. With this structure, a structure where layers with different memory densities are subsequently layered from the side of the element layer 20 including the arithmetic unit 21 can be obtained. For example, the memory units 33 including the memory cells 34 having different circuit structures can be applied to the element layers 30_1 to 30_n. By providing a NOSRAM described later in the element layer 30 positioned close to the arithmetic unit 21 and a DOSRAM described later in the element layer 30 positioned far from the arithmetic unit 21, the access speed can be varied in order of proximity to the element layer 20 including the arithmetic unit 21.

The same circuit structure can be employed for the memory cells 34 provided in the memory units 33 in more than one layer of the element layers 30_1 to 30_n. With this structure, manufacturing steps using the same photomask can be employed for a plurality of element layers. Thus, the memory units 33 can be formed in the perpendicular direction by repeating the same manufacturing steps, so that manufacturing cost can be reduced.

Note that in the memory units 33 included in the element layers 30_1 to 30_n formed over the element layer 20, wiring spaces or transistor sizes can be designed to differ between the element layers 30_1 to 30_n. In this case, specifications such as the access speed or the like of the memory unit 33 can be different between the element layers 30_1 to 30_n, so that the memory units 33 with the same area can have different memory capacities and different access speeds.

The off-state current of an OS transistor is extremely low. Accordingly, electric charge corresponding to data written to the memory cell 34 can be retained in the capacitor for a long time. In other words, data once written to the memory cell 34 can be retained for a long time. Therefore, the frequency of data refresh can be reduced, and the power consumption of the semiconductor device 10 of one embodiment of the present invention can be reduced. A memory unit including a memory cell that includes an OS transistor is referred to as an “OS memory” in some cases.

The memory unit 33 that is provided with the memory cell 34 including the OS transistor can be referred to as a DOSRAM (Dynamic Oxide Semiconductor Random Access Memory). The DOSRAM refers to a RAM including a 1T (transistor) 1C (capacitor) memory cell. The DOSRAM is a DRAM formed using an OS transistor and is a memory that temporarily stores information transmitted from the outside. The DOSRAM is a memory utilizing a low off-state current of an OS transistor. Since the DOSRAM is a 1TIC memory cell, a large memory capacity can be achieved in the memory unit 33. Furthermore, with the use of an OS transistor, the data retention period can be longer than that of a DRAM including a Si transistor.

The Si transistor included in the DRAM has a higher off-state current than the OS transistor. Thus, in order to reduce the off-state current of the Si transistor, the channel length needs to be long. To obtain a long channel length in a limited area, the structure in which the channel length is made longer in the depth direction of the substrate is effective; however, in this case, reducing the thickness of the substrate is difficult. In addition, the capacitance value of a capacitor needs to be increased to retain charge. Therefore, the height of the capacitor needs to be increased as in a trench-type (deep groove-shaped) structure. Thus, the memory cell of the DRAM including the Si transistor has a large cell size in the Z direction.

In contrast, the off-state current of the OS transistor included in the DOSRAM is extremely low. Thus, in order to reduce the off-state current, the channel length does not need to be long. The thickness of one element layer of the element layer 30 can be smaller than that of the DRAM. In addition, since the off-state current of the OS transistor is extremely low in the DOSRAM, the capacitance of the capacitor can be estimated to be low. For example, the capacitor can be a parallel-plate-type capacitor instead of a trench-type capacitor (a deep groove-shaped capacitor). The parallel-plate-type capacitor is more easily manufactured than a trench-type capacitor. Accordingly, the yield can be increased and the number of manufacturing steps can be reduced. Such a structure of the DOSRAM in which the element layers can be thinned, the yield can be high, and the number of manufacturing steps can be reduced is particularly effective in application to the memory units 33 of the element layers 30_1 to 30_n of one embodiment of the present invention.

In other words, the memory unit 33 provided with the memory cell 34 including the OS transistor can be a NOSRAM (Nonvolatile Oxide Semiconductor Random Access Memory). A memory cell in the NOSRAM is a two-transistor (2T) or three-transistor (3T) gain cell. In the NOSRAM, data is rewritten by charge and discharge of the capacitor; therefore, rewriting can be performed theoretically with no limit on the number of rewrites and at low energy. Moreover, the NOSRAM can have higher data access speed than a DOSRAM. Therefore, the NOSRAM is a memory that can operate at higher speed, has lower power consumption, and has higher rewrite endurance than the DOSRAM.

In the case where data in the NOSRAM is multilevel data with three or more levels, data capacity per memory cell can be larger than that of the DOSRAM. Furthermore, the NOSRAM can nondestructively read the written data and thus is suitable for long-time data retention. In contrast, the DOSRAM destructively read the written data and thus is suitable to be applied to layers of memory units with high access frequency.

Furthermore, an OS transistor has electrical characteristics superior to those of a Si transistor in a high-temperature environment. Specifically, the ratio between an on-state current and an off-state current is large even at a high temperature higher than or equal to 125° C. and lower than or equal to 150° C.; thus, a favorable switching operation can be performed. The OS transistor operates favorably within the range from −40° C. to 190° C. In other words, the OS transistor has significantly high heat resistance. This heat resistance is higher than the heat resistance of a phase change memory (PCM) (higher than or equal to −40° C. and lower than or equal to 150° C.), the heat resistance of a resistance random access memory (ReRAM) (higher than or equal to −40° C. and lower than or equal to 125° C.), the heat resistance of a magnetoresistive random access memory (MRAM) (higher than or equal to −40° C. and lower than or equal to 105° C.), and the like.

In the schematic diagrams illustrated in FIG. 1B, components included in the semiconductor device 10 are illustrated apart from each other for easy understanding of the arrangement of components. Although components provided in the same layer are preferably formed in the same step, one embodiment of the present invention is not limited thereto. For example, components formed in different steps may be integrated by an attachment technique or the like.

The memory units 33 provided with the memory cell 34 are stacked in the direction perpendicular or substantially perpendicular to the surface of the element layer 20. In other words, the element layers 30_1 to 30_n are layered in the direction perpendicular or substantially perpendicular to the surface of the substrate provided with the element layer 20. With this structure, the number of memory cells 34 provided per unit area can be increased. Accordingly, the memory density can be increased.

In the schematic cross-sectional view illustrated in FIG. 1B, the direction perpendicular or substantially perpendicular to the surface of the element layer 20 is defined as a Z-axis direction in order to explain the position of components. Note that for easy understanding, the Z-axis direction is sometimes referred to as a direction perpendicular to the surface of the element layer 20 in this specification. Note that “substantially perpendicular” refers to a state where an arrangement angle is greater than or equal to 85 degrees and less than or equal to 95 degrees.

Note that in this specification, the drawings, and the like, an X direction, a Y direction, and a Z direction are sometimes defined to describe arrangement of components. For example, in the schematic diagram illustrated in FIG. 1B, the X direction, the Y direction, and the Z direction are defined to describe the arrangement of components included in the semiconductor device 10. The X direction, the Y direction, and the Z direction are perpendicular or substantially perpendicular to each other.

With the structure in which data is input and output between the element layer 20 and the element layers 30_1 to 30_n as illustrated in FIG. 1A, the memory unit 33 provided in the element layers 30_1 to 30_n can be a layered memory unit. Thus, the memory unit 33 can be used as a cache memory of the arithmetic unit 21. The cache memory is a memory used for reducing delays of a main memory device, a bus, and the like to fill the difference in performance between the arithmetic unit 21 and an external memory device when the arithmetic unit 21 such as a CPU input, output, or update data, instruction, and the like. When a memory unit capable of being used as a cache memory with a large capacity is provided above the arithmetic unit, the frequency of access to data of an external memory device (a main memory or an auxiliary memory device) due to cache miss can be reduced, so that power efficiency can be improved.

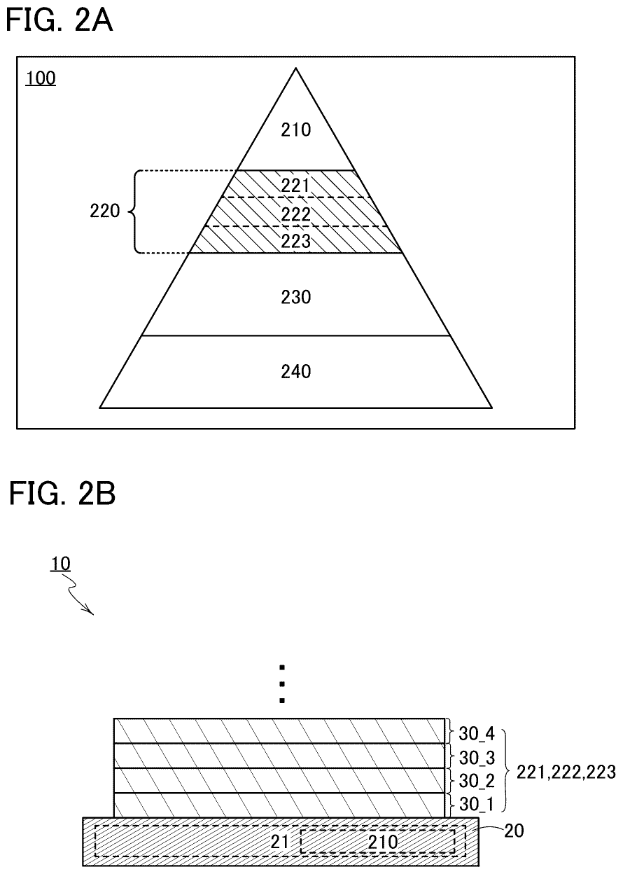

In FIG. 2A, memory devices (including the above-described memory units included in the element layers 30) included in an arithmetic processing system 100 including the semiconductor device 10 are hierarchized in order of access speed: a memory unit 210, a memory unit 220, a memory unit 230, and a memory unit 240.

The memory unit 210 positioned at the highest level corresponds to a memory unit such as a register, a flip-flop, or an SRAM (Static Random Access Memory) in the arithmetic unit 21 provided in the element layer 20. The memory unit 220 positioned at the next level of the memory unit 210 corresponds to the memory unit 33 included in the element layer 30. The memory unit 230 corresponds to a main memory device (a main memory). The DRAM or the like corresponds to the main memory device (the main memory). The memory unit 240 corresponds to an auxiliary memory device. A storage-class memory such as a flash memory, a hard disk drive, and a solid state drive corresponds to the auxiliary memory device.

The memory unit 220 corresponds to the above-described cache memory. The memory unit 220 can be subdivided into layers such as an L1 cache 221, an L2 cache 222, and an L3 cache 223 depending on the access speed and memory capacity. The memory unit 220 may be subdivided into two levels or four or more levels.

In the arithmetic processing system 100, a memory unit positioned at the higher level is required to operate at higher speed. In addition, a memory unit positioned at the lower level is required to have a larger capacity and a higher density (or a smaller area per bit). For example, the memory unit 210 is required to have a high operation speed since data used for arithmetic operation in an integrated circuit or the like is held. In addition, for example, the L1 cache, which is positioned at the top level in the memory unit 220 is required to have a high operation speed since the frequency of access is the highest. In contrast, although the L2 cache, the L3 cache, and the like are not required to operate as fast as the L1 cache, they are required to have a larger capacity and a smaller area per bit than the L1 cache.

One embodiment of the present invention has been made in view of the above objects, and a cache memory is constituted of the element layers 30 including OS transistors that can be stacked in the arithmetic unit 21 functioning as a CPU in the semiconductor device 10. The L3 cache is stacked above the L1 cache and the L2 cache. The L2 cache is stacked above the L1 cache. The L1 cache is stacked above the arithmetic unit 21. That is, as illustrated in FIG. 2B, in the semiconductor device 10, the L1 cache 221, the L2 cache 222, and the L3 cache 223 are formed using the element layers 30 (element layers 30_1 to 30_4) provided above the element layer 20 that is provided with the arithmetic unit 21 including the memory unit 210.

Note that a modification example such as the structure in which the L1 cache 221 is provided on the element layer 20 side and the L2 cache 222 and the L3 cache 223 are provided on the element layer 30 side may be employed. Alternatively, a modification example such as the structure in which the L1 cache 221 and the L2 cache 222 are provided on the element layer 20 side and the memory units of the L3 cache 221 and the subsequent layers (e.g., an L4 cache) are provided on the element layer 30 side may be employed. With this structure, the access speed of the memory unit of the L1 cache 221 or the like close to the arithmetic unit 21 can be increased.

Such a structure can increase the memory capacity of the memory unit 33 functioning as a cache memory, make it easy to place the circuit units of the arithmetic unit 21 functioning as a CPU, and provide a semiconductor device with low power consumption with a small area and high arithmetic capability.

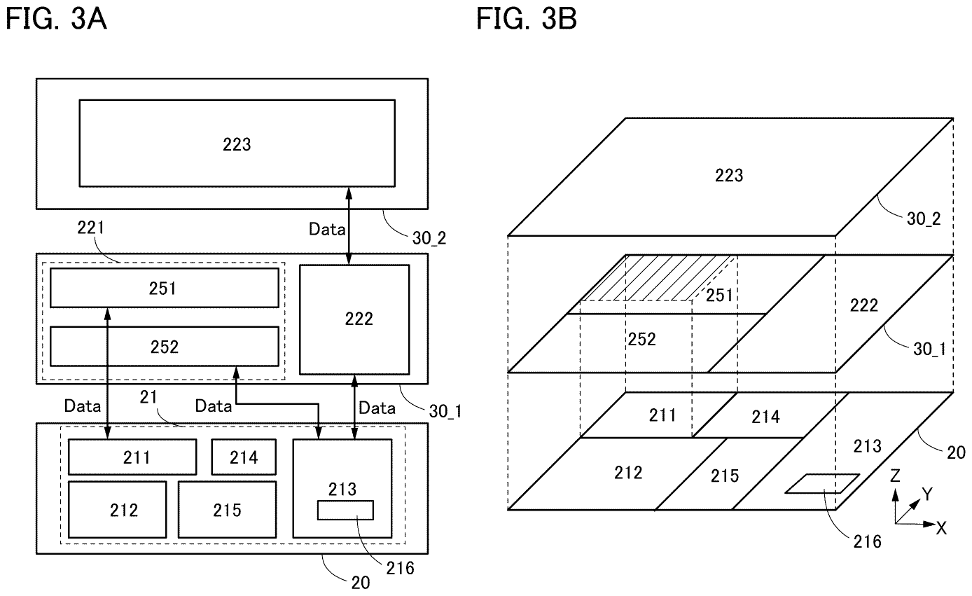

FIG. 3A is a block diagram illustrating a structure example in which the above-described structure is applied to the arithmetic unit 21 (the register provided in the arithmetic unit 21 corresponds to the memory unit 210), the L1 cache 221, the L2 cache 222, and the L3 cache 223 (corresponding to the memory unit 220). FIG. 3B is a schematic view illustrating the arrangement of the blocks described with reference to FIG. 3A. FIG. 3B illustrates the arrangement of the circuit units in the element layer 20 where the arithmetic unit is provided, the arrangement of the memory units in the element layer 30_1 where the L1 cache and the L2 cache are provided, and the arrangement of the memory units in the element layer 30_2 where the L3 cache is provided. In FIG. 3B, the element layer 20, the element layer 30_1, and the element layer 30_2 are stacked in the Z direction.

The arithmetic unit 21 provided in the element layer 20 includes circuit units such as an instruction decoder 211, a branch prediction unit 212, a load/store unit 213, an arithmetic logic unit 214, a floating-point arithmetic unit 215, and the like. In the element layer 20, the arithmetic unit 21 including a plurality of circuit units accounts for a large portion of a finite area. Therefore, it is not easy to increase the memory capacity of the L1 cache 221 or the L2 cache 222 in a layer close to the arithmetic unit in the arithmetic processing system 100 without reducing the arithmetic capability of the arithmetic unit 21 in the element layer 20.

In one embodiment of the present invention, the L1 cache 221 provided in the element layer 30_1 has a minimum necessary memory capacity and is provided in the element layer 30_1 that is different from the element layer 20 provided with the memory unit 210. The L1 cache 221 is divided into an instruction cache 251 and a data cache 252. The memory capacity of the L2 cache 222 is limited like the L1 cache 221. Furthermore, the L3 cache 223 is provided in an element layer that is different from the element layer 30_1 in which the L1 cache 221 and the L2 cache 222 are provided because the L3 cache 223 needs to have a larger memory capacity than the L1 cache 221 and the L1 cache 221.

Providing the instruction cache 251 and the data cache 252 which are the L1 cache 221 in the element layer 30_1 can reduce the area of the L1 cache 221 provided in the element layer 20, so that the area of the arithmetic unit 21 in the element layer 20 can be reduced. Thus, the chip size of the semiconductor device 10 in which the element layers 20 and the element layers 30_1 to 30_n are stacked can be reduced. Consequently, the yield of the semiconductor device 10 can be improved. Furthermore, the flexibility of the arrangement of the L1 cache 221, such as the instruction cache 251 and the data cache 252, can be increased; thus, the instruction cache 251 and the data cache 252 can be arranged in a square or substantially square-shaped region. On the other hand, in the case where the L1 cache 221 is provided in the element layer 20, the flexibility of the arrangement of the L1 cache 221 is low; thus, the shapes of the instruction cache 251 and the data cache 252 are constrained. When the shapes of the instruction cache 251 and the data cache 252 are constrained, access speed is decreased in some cases due to, for example, the wiring length being increased. That is, the access speed of the L1 cache 221 can be increased compared to the case where the L1 cache 221 is provided in the element layer 20.

The instruction decoder 211 decodes a program stored in the instruction cache 251, and generates a control signal that specifies whether the instruction is a load instruction, a store instruction, an arithmetic instruction, or a branch instruction, or the like and register data and memory access necessary for execution of the instruction.

The branch prediction unit 212 predicts a branch condition (whether the branch is taken or not) in the branch instruction and performs speculative execution (the address of the next instruction is issued in the case where the branch is predicted to be not taken and the address of the branch target is issued in the case where the branch is predicted to be taken).

Since the instruction decoder 211 and the branch prediction unit 212 need to execute processing on data stored in the instruction cache 251 at high speed, a structure where the instruction decoder 211 and the branch prediction unit 212 are arranged near the instruction cache 251 is effective. For example, the instruction cache 251 provided in the element layer 30_1 is provided in a region above the instruction decoder 211 provided in the element layer 20 (a region with hatching in FIG. 3B). This structure enables the instruction decoder 211 and the branch prediction unit 212 to execute high-speed processing on the data stored in the instruction cache 251 at high speed.

The load/store unit 213 includes a general-purpose register 216 or the like. The general-purpose register 216 corresponds to part of the memory unit 210 included in the upper level in the arithmetic processing system 100. The load/store unit 213 stores (loads) data stored in the data cache 252 or the general-purpose register 216 in the general-purpose register 216 or the like, or stores data stored in the general-purpose register 216 or the like in the data cache 252 or the general-purpose register 216.

The load/store unit 213 needs to perform processing on the data stored in the data cache 252 at high speed. Furthermore, the load/store unit 213 needs to access the data of the L2 cache 222 when the data cache 252 does not have data; thus, placing the load/store unit 213 near the data cache 252 and the L2 cache 222 is effective. In that case, the data cache 252 or the L2 cache 222 provided in the element layer 30_1 is preferably provided in a region above the load/store unit 213 provided in the element layer 20. For example, a structure where the data cache 252 provided in the element layer 30_1 and the load/store unit 213 provided in the element layer 20 include a region where they overlap with each other, a structure where the L2 cache 222 provided in the element layer 30_1 and the load/store unit 213 provided in the element layer 20 include a region where they overlap with each other, or a structure where the data cache 252 and the L2 cache 222 provided in the element layer 30_1 and the load/store unit 213 provided in the element layer 20 include a region where they overlap with each other, is employed. With this structure, the load/store unit 213 can execute processing on the data stored in the data cache 252 or the L2 cache 222 at high speed.

The arithmetic logic unit 214 executes four arithmetic operations and logic operations on the data stored in the general-purpose register 216 and the like, and stores results in the general-purpose register 216 and the like. Since the arithmetic logic unit 214 needs to perform processing on the data stored in the general-purpose register 216 and the like at high speed, placing the arithmetic logic unit 214 near the load/store unit 213 is effective.

The floating-point arithmetic unit 215 performs a floating-point arithmetic operation on data stored in a floating-point register or the like, and stores results in the floating-point register (not illustrated) or the like. The floating-point register is provided in the floating-point arithmetic unit 215.

In the case where there is no data in the L2 cache 222, data in the L3 cache 223 needs to be accessed; thus providing the L2 cache 222 near the L3 cache 223 is effective. For example, the L3 cache 223 provided in the element layer 30_2 is preferably provided in a region above the L2 cache 222 provided in the element layer 30_1. For example, a structure in which the L2 cache 222 provided in the element layer 30_1 and the L3 cache 223 provided in the element layer 30_2 include a region where they overlap with each other is employed. With this structure, the L2 cache 222 can execute processing on data stored in the L3 cache 223 at high speed.

The above structure can increase memory capacity of the cache memory, make it easy to arrange the circuit units of the arithmetic unit 21 functioning as a CPU, and provide a semiconductor device with a small area, high arithmetic capability, and low power consumption.

Although the circuit arrangement of the arithmetic unit 21, the L1 cache 221, the L2 cache 222, and the L3 cache 223 in the element layer 20, the element layer 30_1, and the element layer 30_2 is described with reference to FIG. 3A and FIG. 3B, another structure may be employed. For example, in a register in each circuit unit included in the arithmetic unit 21, a nonvolatile memory for retaining (backup) data in the register can be added. The nonvolatile memory has a function of retaining data in the register in each circuit unit included in the arithmetic unit 21.

When the register and the nonvolatile memory are combined in each circuit unit included in the arithmetic unit 21, the register in each circuit unit included in the arithmetic unit 21 can be a nonvolatile register. The nonvolatile register is capable of backing up data in a low-power state such as clock gating in which a clock signal is periodically stopped or power gating in which supply of power supply voltage is stopped.

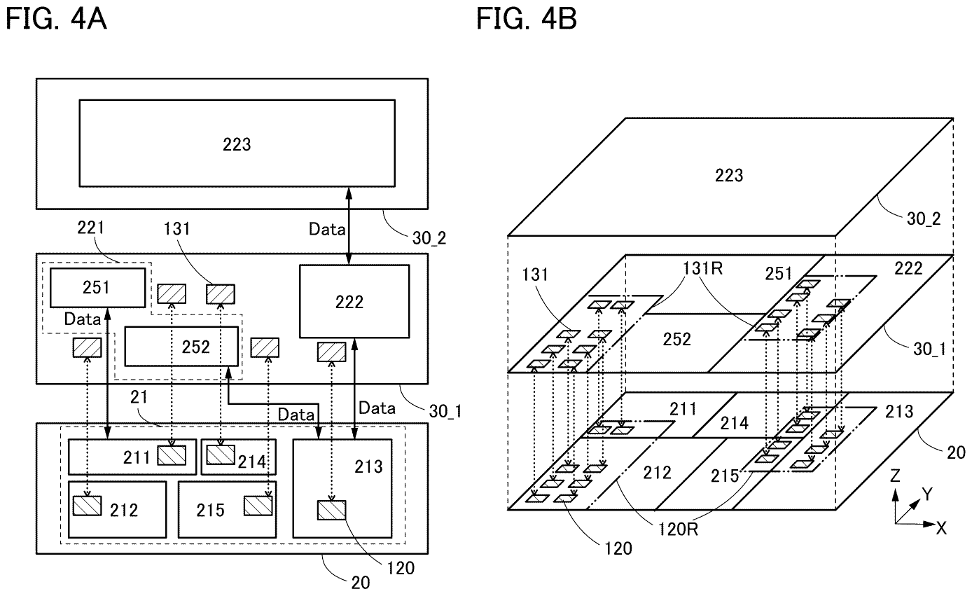

FIG. 4A is a block diagram illustrating a structure example including a register in each circuit unit included in the arithmetic unit 21 and a nonvolatile memory provided in the element layer 30_1 in the above-described structure of FIG. 3A. FIG. 4B is a schematic view illustrating the arrangement of the blocks described with reference to FIG. 4A.

The element layer 20 illustrated in FIG. 4A and FIG. 4B includes a register 120 included in each circuit unit in the arithmetic unit 21. The register 120 provided in the element layer 20 is a circuit including a Si transistor. The element layer 30_1 illustrated in FIG. 4A and FIG. 4B includes a nonvolatile memory 131 that retains data in the register 120 in each circuit unit included in the arithmetic unit 21. The nonvolatile memory 131 retains data by utilizing a low off-state current of an OS transistor. Dotted arrows indicating storing (also referred to as saving or backing up) and restoring (also referred to as loading or recovering) of data is shown between the register 120 provided in the element layer 20 and the nonvolatile memory 131 provided in the element layer 30_1. The register 120 is referred to as a volatile register in some cases. The nonvolatile memory 131 is referred to as a backup circuit in some cases.

In the element layer 20, the register 120 is provided in a region in each circuit unit included in the arithmetic unit 21. That is, the register 120 is distributed in the instruction decoder 211, the branch prediction unit 212, the load/store unit 213, the arithmetic logic unit 214, and the floating-point arithmetic unit 215. In the element layer 30_1, the nonvolatile memory 131 is provided in a region different from a region where a cache memory is provided. That is, the nonvolatile memory 131 is placed in a region different from the region where the L2 cache 222, the instruction cache 251, and the data cache 252 are provided.

The register 120 and the nonvolatile memory 131 illustrated in FIG. 4A and FIG. 4B with hatching are preferably provided to include a region where the circuits overlap with each other. That is, the nonvolatile memory 131 is preferably provided to include a region overlapping with the register 120.

For example, as illustrated in FIG. 4B, a region 120R of the element layer 20 where the register 120 is provided an area that overlaps with a region 131R of the element layer 30_1 where the nonvolatile memory 131 is provided. With this structure, a signal transmission distance between the register 120 and the nonvolatile memory 131 can be shortened and resistance and parasitic capacitance of wirings between the circuits can be significantly reduced, so that power consumption and signal delay can be reduced.

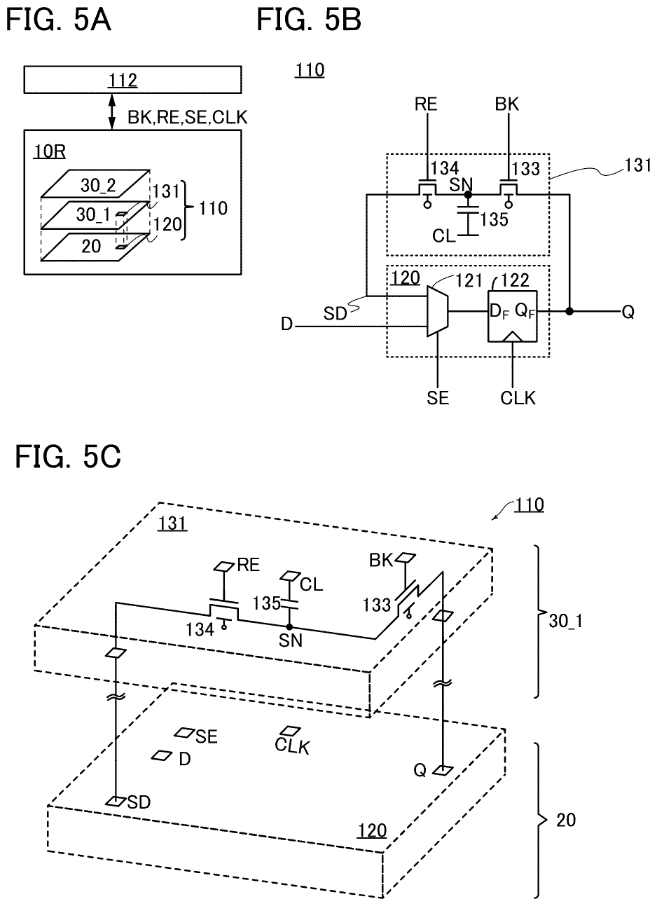

FIG. 5A is a block diagram of a semiconductor device 10R including a nonvolatile register 110 composed of the register 120 and the nonvolatile memory 131 described with reference to FIG. 4A and FIG. 4B. FIG. 5B is a diagram illustrating a circuit structure example of the nonvolatile register 110 including the register 120 and the nonvolatile memory 131 described with reference to FIG. 4A and FIG. 4B. FIG. 5C is a schematic perspective view of the nonvolatile register 110 illustrated in FIG. 5B.

FIG. 5A illustrates the semiconductor device 10R and a state control unit 112 capable of switching the semiconductor device 10R to a low-power state such as power gating or clock gating in accordance with the state of the semiconductor device 10R.

The state control unit 112 is a circuit that outputs a control signal for performing switching between a plurality of tasks and processing the tasks in accordance with a signal such as an interrupt signal input from the outside or a sleep signal generated by the semiconductor device 10R. The state control unit 112 generates a clock signal CLK and various signals (a signal BK, a signal RE, and a signal SE). The clock signal CLK and the various signals are input to the semiconductor device 10R.

The signal BK is a signal for controlling a saving of data retained in the flip-flop in the register 120. By the data saving, the data in the register 120 is retained in the nonvolatile memory 131.

The signal RE is a signal for controlling loading of data retained in the nonvolatile memory 131. By data loading, the data retained in the nonvolatile memory 131 is retained in the flip-flop in the register 120.

The signal SE is a switch signal for a selector. The clock signal CLK is a signal for operating the flip-flop in the register 120.

The nonvolatile register 110 illustrated in FIG. 5B includes the register 120 and the nonvolatile memory 131. The register 120 includes a selector 121 and a flip-flop 122. The nonvolatile memory 131 can be formed with transistors 133 and 134, which are OS transistors, and a capacitor 135. In the nonvolatile memory 131, electric charges can be accumulated in the capacitor 135 by utilizing the extremely low off-state current of the OS transistors, and a potential corresponding to data written to the register 120 can be retained for a long period.

The nonvolatile register 110 retains data input from a terminal D or data input from a terminal SD of the register 120 in the register 120 and outputs the data from a terminal Q in accordance with the clock signal CLK. The data of the register 120 output from the terminal Q is saved in the nonvolatile memory 131 by control of the signal BK. Data of the nonvolatile memory 131 is output to the terminal SD by control of the signal RE and is loaded into the register 120.

The selector 121 has a function of supplying a signal of the terminal D or the terminal SD to the register 120 in accordance with the signal SE. The terminal D is a terminal that supplies data input from the outside of the nonvolatile register 110. The terminal SD is a terminal that supplies data input from the nonvolatile memory 131.

Although the flip-flop 122 illustrated in FIG. 5B is a D flip-flop, the flip-flop 122 is not limited thereto. A flip-flop prepared in a standard circuit library can be applied. A transistor included in the flip-flop 122 is a Si transistor, and the flip-flop 122 can retain one piece of data by including a circuit such as an inverter loop. The flip-flop 122 retains data in an input terminal DF and outputs the retained data to the terminal Q through an output terminal Q_{F} in accordance with the clock signal CLK.

The nonvolatile memory 131 is connected to the terminal Q and the terminal SD. In the nonvolatile memory 131, a terminal (wiring) connected to the terminal Q is referred to as an input terminal and a terminal (wiring) connected to the terminal SD is referred to as an output terminal. The above-described output terminal Q_{F} of the flip-flop 122 is electrically connected to the input terminal of the nonvolatile memory 131, and the input terminal DF of the flip-flop 122 is electrically connected to the output terminal of the nonvolatile memories 131.

The nonvolatile memory 131 includes the transistor 133, the transistor 134, and the capacitor 135. The other electrode of the capacitor 135 is connected to a wiring CL. The transistor 133 is provided between the capacitor 135 and the terminal Q. The transistor 134 is provided between the capacitor 135 and the terminal SD. One electrode of the capacitor 135 of the nonvolatile memory 131 is illustrated as a node SN.

In the nonvolatile memory 131, the signal BK is supplied to the gate of the transistor 133 and the signal RE is supplied to the gate of the transistor 134. The signal BK is a signal for saving data retained in the flip-flop 122 to a plurality of nonvolatile memories 131. The signal RE is a signal for loading the data retained in the nonvolatile memory 131 to the flip-flop 122.

The transistors 133 and 134 are OS transistors. The transistors 133 and 134 have back gates in the illustrated structure. Supplying constant voltages to the back gates of the transistors 133 and 134 allows control of transistor characteristics. At least the transistors 133 and 134 are preferably OS transistors. Because of extremely low off-state current, which is a feature of the OS transistor, a decrease in the voltage of the node SN can be inhibited and almost no power is consumed to retain data; therefore, the nonvolatile memory 131 has a nonvolatile characteristic. Data is rewritten by charging and discharging of the capacitors 135; hence, there is theoretically no limitation on rewrite cycles of the nonvolatile memory 131, and data can be written and read out with low energy.

In the nonvolatile memory 131, the OS transistors function as switches. In an OS transistor, which is an n-channel transistor, when a signal supplied to a gate is set to high level (hereinafter expressed as =“H), a conduction state can be established between a source and a drain, and when the signal supplied to the gate is set to low level (hereinafter expressed as =“L”), a non-conduction state can be established between the source and the drain. Furthermore, when the signal SE is set to high level (hereinafter expressed as =“H”), a signal of the terminal SD is selected in the selector 121, and when the signal SE is set to low level (hereinafter expressed as =“L”), a signal of the terminal D is selected in the selector 121.

For example, when the signal BK=“H” is set in the nonvolatile memory 131, data retained in the flip-flop 122 can be written to the node SN in the nonvolatile memory 131. Furthermore, when RE=“H” and SE=“H” are set, the data in the node SN of the nonvolatile memory 131 can be written back to the flip-flop 122.

It is extremely preferable that all the transistors in the nonvolatile memories 131 and included in the nonvolatile memories 131 be OS transistors. As illustrated in FIG. 5C, the nonvolatile memory 131 can be stacked over the register 120 formed using a silicon CMOS circuit.

Since the number of elements of the nonvolatile memory 131 is much smaller than that of the register 120, there is no need to change the circuit configuration and layout of the register 120 in order to stack the nonvolatile memories 131. That is, the nonvolatile memory 131 is a circuit with extremely high versatility. Since the nonvolatile memory 131 can be provided in a region where the register 120 is formed, area overhead can be zero even when the nonvolatile memory 131 is incorporated. Since energy required for retaining data in the backup circuit is small, it is possible to frequently save or load data in the semiconductor device 10R.

When the nonvolatile memory 131 is provided, parasitic capacitance due to the transistor 133 is added to the node Q; however, the operation of the register 120 is not affected because the parasitic capacitance is lower than that due to a logic circuit connected to the node Q. That is, even when the nonvolatile memory 131 is provided, the performance of the nonvolatile register 110 does not substantially decrease.

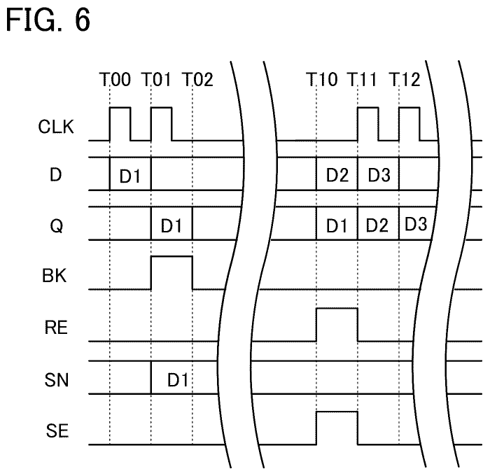

FIG. 6 is an example of a timing chart showing an operation of the nonvolatile register 110 illustrated in FIG. 5B. Note that in FIG. 6, T00 to T02 and T10 to T12 represent time. FIG. 6 illustrates the clock signal CLK, the terminal D, the terminal Q, the signal BK, the signal RE, the node SN, and the signal SE, which is supplied to the selector 121. The flip-flop 122 stores data of the input terminal DF and performs output from the output terminal Q_{F} in synchronization with a rising edge of the clock signal CLK (a waveform switched from the L level to the H level).

In Time T00 to T02, the operation of retaining data D1 of the register 120 in the nonvolatile memory 131 is described.

At Time T00, the data DI is supplied to the terminal D.

At Time T01, the register 120 stores the data D1 supplied to the terminal D and performs output from the output terminal Q_{F} in synchronization with the rising edge of the clock signal CLK. At Time T1, the signal BK=“H”, the signal RE=“L”, and the signal SE =“L” are set, whereby the data D1 of the register 120 is retained in the nonvolatile memory 131.

After Time T02, the data DI can be retained in the nonvolatile memory 131. Thus, clock gating of the clock signal CLK, power gating to the semiconductor device 10R, and the like can be performed.

It is effective to perform clock gating of the clock signal CLK and power gating to the semiconductor device 10R in a period during which data necessary for arithmetic operation is copied to the cache due to a cache error or the like. In the case of the cache error, a memory unit at the lower level (a memory unit with large memory capacity and low access speed) is accessed, the data is copied from the memory unit at the lower level, and then the data is accessed. In this case, the floating-point arithmetic unit 215 that performs arithmetic operation based on four arithmetic operations or the like goes into a standby state; thus, the above-described structure in which clock gating of the clock signal CLK and power gating to the semiconductor device 10R are performed is effective.

In Time T10 to T12, the case where the data D1 retained in the nonvolatile memory 131 is loaded into the register 120 is described.

At Time T10, BK=“L”, RE=“H”, and SE=“H” are set, whereby the data D1 retained in the nonvolatile memory 131 can be written back to the register 120. Data D2 is supplied to the terminal D.

At Time T11, the register 120 stores the data D2 supplied to the terminal D and performs output from the output terminal Q_{F} in synchronization with the rising edge of the clock signal CLK. Data D3 is supplied to the terminal D.

At Time T12, the register 120 stores the data D3 supplied to the terminal D and performs output from the output terminal Q_{F} in synchronization with the rising edge of the clock signal CLK.

As described with reference to FIG. 6, a structure of saving the data of the interrupted task and loading the data of the task to be resumed can be formed. In one embodiment of the present invention, the saved data can be stored in the data retention circuits in accordance with the switch of the task. With this structure, data is saved and loaded at the time when an interrupt signal is input, whereby program processing can be sequentially executed. Thus, more efficient data processing can be achieved.

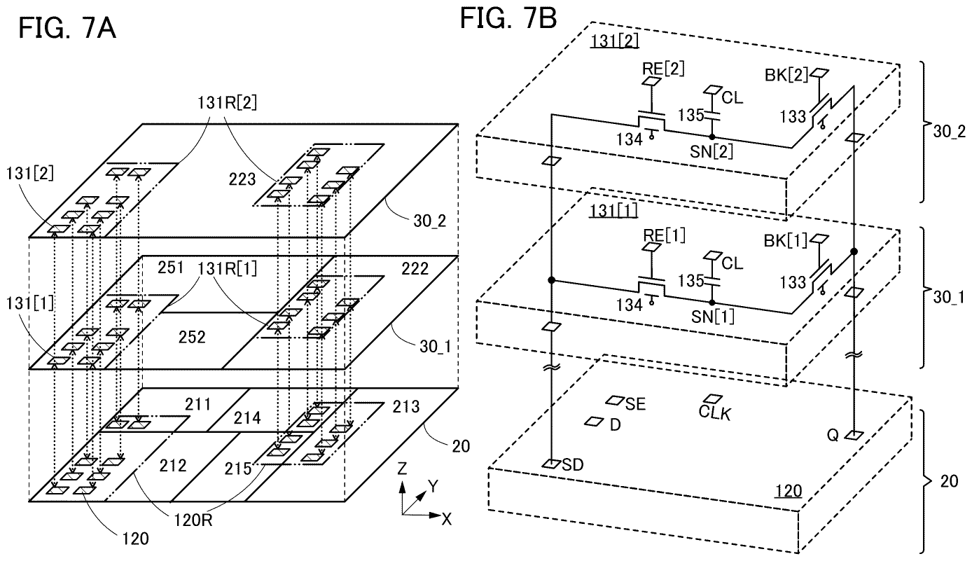

Note that the nonvolatile memories 131 provided above the register 120 can be provided across the element layers 30_1 to 30_n. For example, as illustrated in FIG. 7A, the nonvolatile memory 131[1] provided in the element layer 30_1 and the nonvolatile memory 131[2] provided in the element layer 30_2 can be provided above the register 120 provided in the element layer 20.

The region 120R provided with the register 120, a region 131R[1] provided with the nonvolatile memory 131[1], and a region 131R[2] provided with the nonvolatile memory 131[2], which are illustrated in FIG. 7A, include a region where they overlap with each other. In this case, transistors and capacitors of the circuits provided in the element layer 20, the element layer 30_1, and the element layer 30_2 can be arranged as illustrated in FIG. 7B. Note that BK[1], BK[2], RE[1], and RE[2] are signals for controlling backup circuits provided in different element layers. Nodes SN[1] and SN[2] are nodes provided in different element layers.

With the structure illustrated in FIG. 7A and FIG. 7B, signal transmission distances between the register 120 and the nonvolatile memory 131[1] and the nonvolatile memory 131[2] can be shortened, and the resistance and parasitic capacitance of wirings between the circuits can be significantly reduced, whereby power consumption and signal delay can be reduced. In the structure illustrated in FIG. 7A and FIG. 7B, different data signals can be retained in the nodes SN[1] and SN[2], thus the data signals retained by saving or loading of the data signals can be switched, which is particularly effective in switching a plurality of tasks, for example.

With the above structure, a semiconductor device capable of backing up data and performing clock gating and power gating of the register can be provided, whereby power consumption can be reduced. In addition, since the process can be resumed from where the last operation execution is interrupted at the time of restoring the data, a semiconductor device with improved computing performance can be provided.

Next, a circuit structure of each of the memory cells in a DOSRAM and a NOSRAM that can be applied to the memory cell 34 of the memory unit 33 will be described.

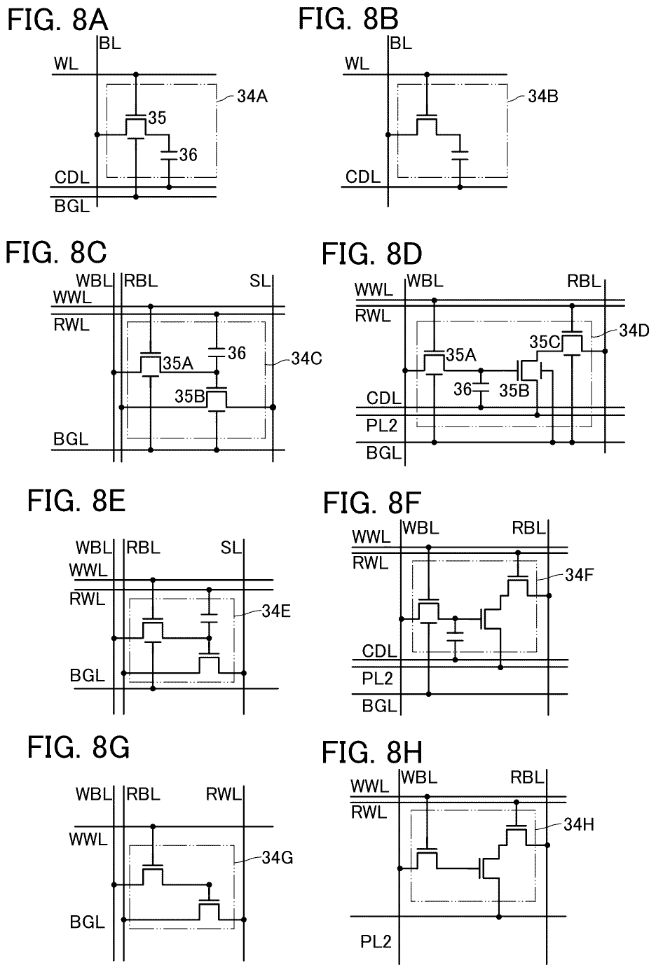

FIG. 8A to FIG. 8H are circuit diagrams each illustrating a structure example of a memory cell including an OS transistor that can be applied to the memory cell 34 described above. As an example of the structure of the memory cell including an OS transistor, a DOSRAM or a NOSRAM can be given as described above.

FIG. 8A illustrates an example of a 1TIC DOSRAM memory cell applicable to the memory cell 34. The memory cell 34A illustrated in FIG. 8A is electrically connected to a word line WL, a bit line BL, a wiring CDL functioning as a capacitor line, and a wiring BGL functioning as a wiring for supplying a back gate voltage. The memory cell 34A includes a transistor 35 and a capacitor 36. A back gate of the transistor 35 is electrically connected to the wiring BGL.

The transistor 35 is an OS transistor. The off-state current of an OS transistor is extremely low. Thus, the memory cell 34A can reduce the frequency of data refresh. Therefore, power required for data retention can be reduced.

FIG. 8B illustrates another structure example of the 1T1C-type DOSRAM memory cell. A memory cell 32B illustrated in FIG. 8B is different from the memory cell 34A illustrated in FIG. 8A in that the transistor 35 is formed using an OS transistor that does not include a back gate.

FIG. 8C illustrates an example of a memory cell in a NOSRAM that is a two-transistor (2T) gain cell applicable to the memory cell 34. A memory cell 34C illustrated in FIG. 8C includes transistors 35A and 35B and the capacitor 36. Note that the capacitor 36 included in the memory cell of a NOSRAM can be omitted when parasitic capacitance such as gate capacitance of a transistor is utilized. The transistor 35A is a write transistor and the transistor 35B is a read transistor. Back gates of the transistors 35A and 35B are electrically connected to the wiring BGL.

Since the write transistor is formed using an OS transistor, charge corresponding to data can be retained continuously by turning off the write transistor. Therefore, the memory cell 34C does not consume power for data retention. Thus, the memory cell 34C can function as a memory cell with low power consumption that can retain data for a long time.

Other structure examples of memory cells applied to NOSRAMs are described with reference to FIG. 8D to FIG. 8H.

A memory cell 34D illustrated in FIG. 8D is a 3T gain cell and includes the transistor 35A, the transistor 35B, and a transistor 35C and the capacitor 36. The transistors 35A, 35B, and 35C are a write transistor, a read transistor, and a selection transistor, respectively. Back gates of the transistors 35A, 35B and 35C are electrically connected to the wiring BGL. The memory cell 34D is electrically connected to wirings RWL and WWL, wirings RBL and WBL, a wiring CDL, and a power supply line PL2. For example, a voltage GND (low-level-side power supply voltage) is input to the wiring CDL and the wiring PL2.

FIG. 8E illustrates another structure example of a 2T gain cell. A memory cell 34E illustrated in FIG. 8E is different from the memory cell 34C illustrated in FIG. 8C in that the read transistor is formed using an OS transistor that does not include a back gate.

FIG. 8F illustrates another structure example of a 3T gain cell. A memory cell 34F illustrated in FIG. 8E is different from the memory cell 34D illustrated in FIG. 8D in that a read transistor and a selection transistor are each formed using an OS transistor that does not include a back gate.

FIG. 8G illustrates another structure example of a 2T gain cell. The memory cell 34G illustrated in FIG. 8G is different from the memory cell 34C illustrated in FIG. 8C in that the transistors 35A and 35B are each formed using an OS transistor without a back gate and the capacitor 36 is omitted.

FIG. 8H illustrates another structure example of a 3T gain cell. The memory cell 34H illustrated in FIG. 8H is different from the memory cell 34D illustrated in FIG. 8D in that the transistors 35A, 35B, and 35C are each formed using an OS transistor without a back gate and the capacitor 36 is omitted.

In the above-described gain cells, a bit line serving as both the wiring RBL and the wiring WBL may also be provided.

In the case where the memory cell 34 is a DOSRAM or a NOSRAM, the wirings (the word lines WL and WWL in FIG. 8A to FIG. 8H) connected to the gates of the transistors (the transistors 35 and 35A in FIG. 8A to FIG. 8H) that are access transistors can be supplied with a voltage that turns off the transistors, and the other portions can be power gated. With this structure, the supply of power supply voltage can be stopped while data is stored in the memory cell 34.

Note that in the case where the memory cells 34A to 34H illustrated in FIG. 8A to FIG. 8H are applied to the memory cells 34 included in the element layers 30 described with reference to FIG. 1B or FIG. 3B, the element layers 30 in different layers preferably include memory cells whose circuit structure or transistor structure are different in each layer.

For example, the instruction cache 251 described with reference to FIG. 3B, which is formed with the element layer 30_1 stacked above the instruction decoder 211 and the branch prediction unit 212 is preferably a memory cell of a NOSRAM, which is advantageous in high-speed operation. Similarly, the data cache 252 and the L2 cache 222 described with reference to FIG. 3B are preferably NOSRAMs that are advantageous in high-speed operation. Note that the L2 cache 222 may be a DOSRAM that is advantageous in increasing the memory density. Similarly, the L3 cache 223 described with reference to FIG. 3B is preferably a DOSRAM that is advantageous in high density.

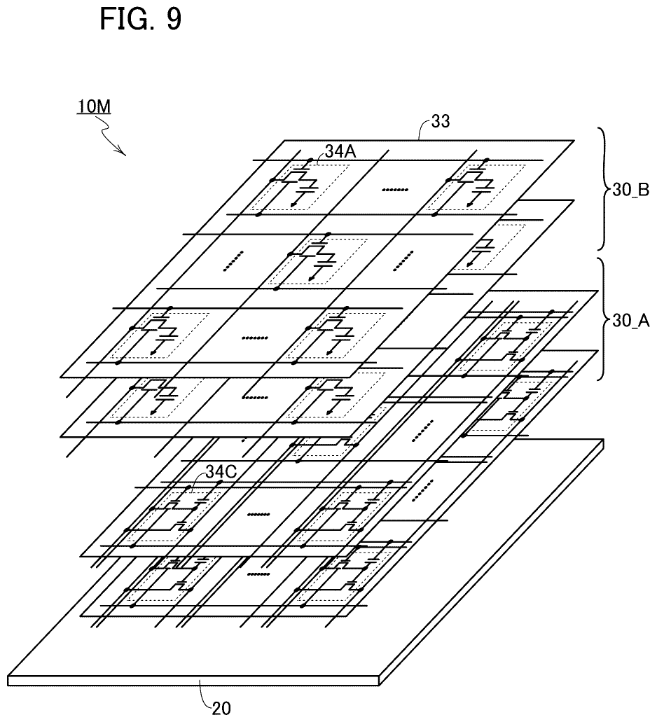

FIG. 9 is a diagram illustrating a structure example of a semiconductor device 10M in which memory cells with different circuit structures are applied to the element layers 30 provided in different layers. In FIG. 9, the element layer 30 provided over the element layer 20 is divided into the element layer 30_A that is the element layer 30 in the lower layer and the element layer 30_B that is the element layer 30 in the upper layer. In the memory unit 33 provided in the element layer 30_A, the memory cell 34C, which is the memory cell of the NOSRAM described with reference to FIG. 8C, is applied. In the memory unit 33 provided in the element layer 30_B, the memory cell 34A, which is the memory cell of the DOSRAM described with reference to FIG. 8A, is applied. With this structure, the semiconductor device with high-speed operation and an increased memory density in the memory unit 220 functioning as a cache memory can be obtained.

Note that the memory unit at the level of the L3 cache 223 or higher is further preferably formed using a DOSRAM utilizing the above-described VFET. For example, when the memory unit 230 corresponding to the main memory is formed using a DOSRAM utilizing VFET, high density of the memory capacitor can be achieved.

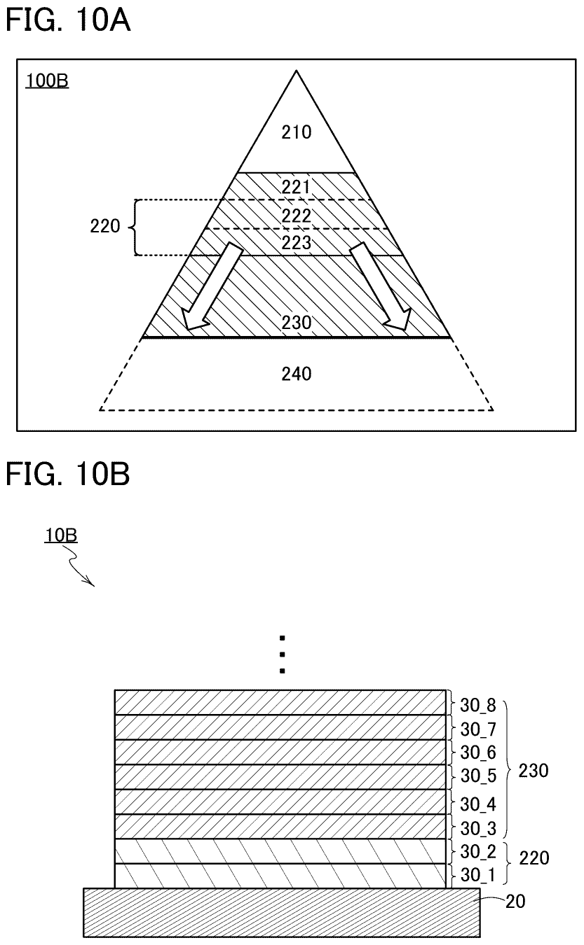

In this case, the memory unit 230 can be used as a cache memory like the memory unit 220. Thus, as in an arithmetic processing system 100B illustrated in FIG. 10A, the size of a level functioning as a cache memory (a layer with hatching in FIG. 10A) can be broadened. That is, when an OS memory is used as the memory unit in the layer of the memory units at the level of the cache memory or lower, a level of the memory units different from that in the conventional arithmetic processing system can be provided.

Note that the memory unit 230 corresponding to the main memory is preferably provided above the element layer 30 provided with the memory unit 220 functioning as the cache memory. For example, as illustrated in FIG. 10B, the memory unit 230 is provided in the element layer 30 (element layers 30_3 to 30_8) provided above the element layer 30 (the element layers 30_1 and 30_2) provided with the memory unit 220. With this structure, the semiconductor device 10B in which the arithmetic unit, the main memory, and the cache memory are integrated can be obtained.

The structure of the semiconductor device 10B in which the arithmetic unit, the main memory, and the cache memory are integrated can reduce the size of a connection wiring or the like as compared with the case where the technique of bonding the memory unit and the arithmetic unit with the use of a through electrode such as TSV is employed. Thus, the amount of data to be accessed between the memory units, such as the arithmetic unit, the main memory, and the cache memory, can be increased. That is, a bandwidth (also referred to as a memory bandwidth) of the memory (the memory unit) can be improved. Note that the bandwidth refers to the data transfer volume per unit time. The structure of the semiconductor device 10B can improve one or both of the memory bandwidth and an access latency. The access latency refers to a period of time from data access to the start of data transmission.

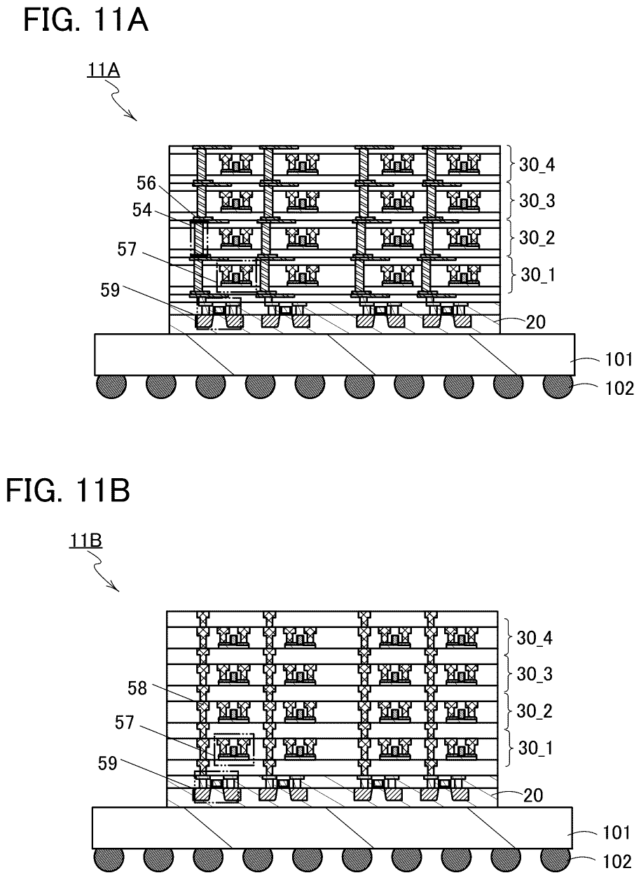

FIG. 11A and FIG. 11B are schematic views each illustrating a structure in which the above-described semiconductor device 10 is applied to an integrated circuit (referred to as an IC chip). The semiconductor device 10 can be one IC chip by mounting a plurality of element layers on a packaging substrate. FIG. 11A and FIG. 11B each illustrate an example of the structure.

A schematic cross-sectional view of an IC chip 11A illustrated in FIG. 11A includes the element layer 20 to be a base die over a package substrate 101 and illustrates the semiconductor device in which four element layers 30_1 to 30_4 are stacked over the element layer 20, for example. FIG. 11A illustrates a Si transistor 59 in the element layer 20 and OS transistors 57 in the element layers 30_1 to 30_4.

Solder balls 102 for connecting the semiconductor device 10 to a printed circuit board or the like are provided on the package substrate 101. The element layers 30_1 to 30_4 are provided with through electrodes 54 provided to penetrate the element layers. The element layers 30_1 to 30_4 are attached to each other using electrodes 56 provided to be exposed on surfaces. As a technique for electrically bonding different layers using the electrodes 56, Cu—Cu bonding can be used. The Cu—Cu bonding is a technique that establishes electrical continuity by connecting Cu (copper) pads.

In the case where a plurality of element layers 30_1 to 30_4 are stacked three-dimensionally as illustrated in FIG. 11A, the element layers are electrically connected to each other by a technique using a through electrode such as a TSV (Through Silicon Via), a Cu—Cu direct bonding technique, or the like. With such a structure, signals and the like supplied to element layers can be distributed via wirings inside the element layers. Furthermore, a memory device applicable to the main memory can be changed into a memory using an OS transistor, so that power consumption can be reduced by utilizing the characteristics of extremely low off-state current of the OS transistor.

As another example, a schematic cross-sectional view of an IC chip 11B illustrated in FIG. 11B includes the element layer 20 to be a base die over the package substrate 101, and illustrates the semiconductor device in which the four element layers 30_1 to 30_4 are stacked over the element layer 20, for example. Electrodes 58 for electrically connecting the element layer 20 and the element layers 30_1 to 30_4 can be provided in a step of manufacturing the Si transistors 59 or the OS transistors 57.

The schematic cross-sectional view of the IC chip 11B illustrated in FIG. 11B can be a monolithic structure where a technique using a through electrode such as a TSV or a Cu—Cu direct bonding technique is not used for connection between the element layer 20 including the Si transistors 59 and the element layers 30_1 to 30_4 including the OS transistors 57. The element layers 30_1 to 30_4 over the element layer 20 can have a structure where wirings provided together with the OS transistors 57 included in the element layers 30_1 to 30_4 are used as the electrodes 58 for connecting the element layers in the upper layers or the lower layers.

The intervals between the wirings provided together with the OS transistors 57 can be more miniaturized than those between through electrodes used for a TSV or a Cu—Cu direct bonding technique. Accordingly, in the structure of the IC chip 11B illustrated in FIG. 11B, the number of electrodes for connecting the element layers in the upper layers and the lower layers can be increased. Accordingly, the number of wirings (the number of signal lines) between the memory unit 33 including the memory cells provided in the element layers 30_1 to 30_4 and the arithmetic unit 21 provided in the element layer 20 illustrated in FIG. 1B and the like can be increased. Therefore, the transfer amount (bandwidth) of signals transmitted and received between the element layer 20 and the element layer 30 can be increased. The increase in the bandwidth can increase the data transfer volume per unit time between the memory unit 33 and the arithmetic unit 21.

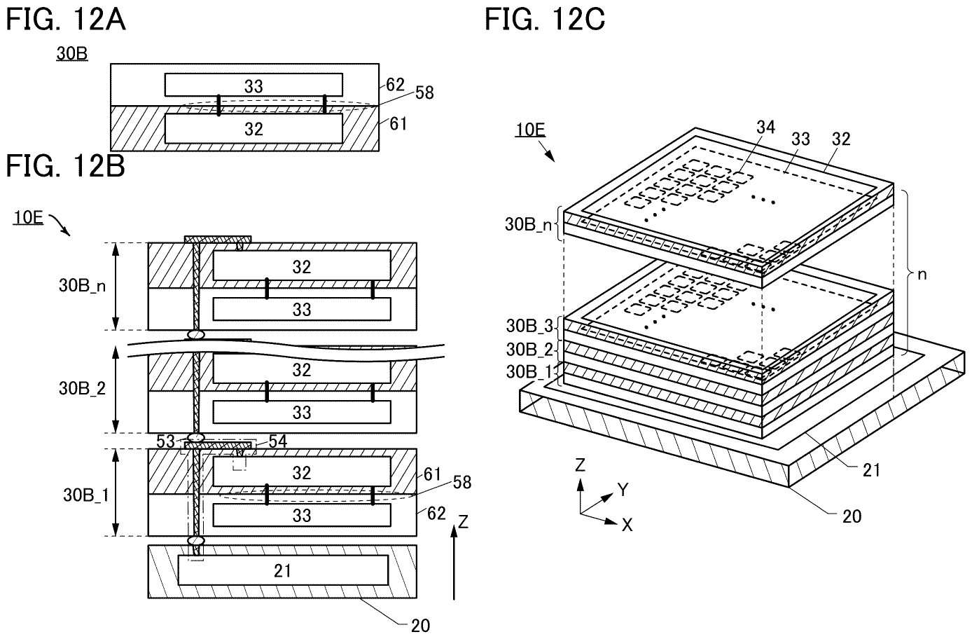

FIG. 12A is a diagram illustrating an element layer 30B with the structure different from that of the element layer 30 illustrated in FIG. 1B, and FIG. 12B is a diagram illustrating a structure example of a semiconductor device 10E in which the element layers 30B (the element layers 30B_1 to 30B_n) illustrated in FIG. 12A are stacked over the element layer 20. FIG. 12C is a schematic view in which the element layers 30B (the element layers 30B_1 to 30B_n) are stacked over the element layer 20.

The element layer 30B illustrated in FIG. 12A includes an element layer 62 stacked over an element layer 61. Like the element layer 20, the element layer 61 includes a Si transistor. The element layer 61 includes a functional circuit unit 32 having a function of an arithmetic circuit, a driver circuit, a control circuit, or the like such as a CPU or GPU formed with a Si transistor. Like the element layer 30, the element layer 62 includes an OS transistor. The element layer 62 includes the memory unit 33.

The electrode 58 for electrically connecting the memory unit 33 and the functional circuit unit 32 is the electrode 58 described with reference to FIG. 11B. The electrode 58 is a wiring that can be formed in a manner similar to that of the layer where OS transistors are provided. Thus, the number of wirings (the number of signal lines) between the memory unit 33 provided in the element layer 62 and the functional circuit unit 32 provided in the element layer 61 can be increased.

In the semiconductor device 10E in FIG. 12B and FIG. 12C, data is input and output between the arithmetic unit 21 and the memory unit 33 through a through electrode 54 provided in the element layer 61 and the element layer 62 and a metal bump 53 provided between the through electrodes 54. The through electrode 54 and the metal bump 53 (also referred to as micro-bump) can make the distance between the arithmetic unit 21 and the memory unit 33 short. In each of the element layers 30B_1 to 30B_n, the functional circuit units 32 having a function of the arithmetic unit can be dispersedly arranged. Thus, in the semiconductor device 10E, the functions of the arithmetic unit 21 can be dispersedly arranged in the functional circuit units 32. For example, a multicore structure can be employed by operating a plurality of CPU cores in parallel.

The through electrodes 54 in each of the element layers 30B_1 to 30B_n may be connected by Cu—Cu bonding without using the metal bumps 53. Alternatively, the through electrodes 54 may be directly connected to each other without using Cu (copper) pads.

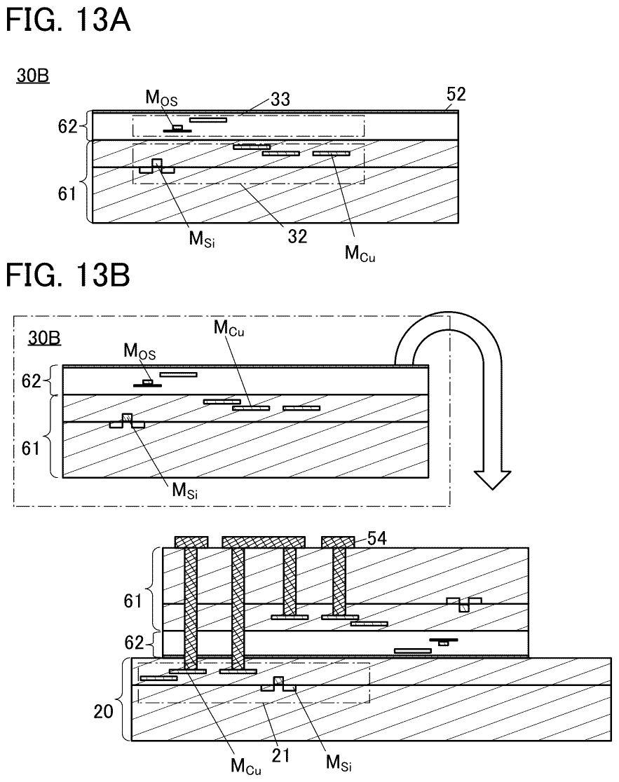

FIG. 13A and FIG. 13B are schematic cross-sectional views illustrating a structure of the direct connection of the element layer 20 and the element layer 30B described with reference to FIG. 12B and FIG. 12C.

The element layer 62 illustrated in FIG. 13A includes an OS transistor Mos included in the memory cell 34 of the memory unit 33. The element layer 61 illustrated in FIG. 13A includes a Si transistor M_{Si} and an electrode M_{CU} included in the arithmetic unit 21. The electrode M_{CU} is an electrode connected at the time of forming the through electrode 54. In the case of using copper (Cu) as the electrode M_{CU}, covering a surface of the electrode with gold (Au) is effective to inhibit the surface from being oxidized at the time of forming the through electrode 54. Note that a structure including a conductor other than copper as the electrode M_{CU} is also possible.

For a bonding layer 52 provided over the element layer 62, silicon oxide (SiOₓ) or the like is suitable because a bonding surface with the element layer 20 can be planarized and hydroxyl groups of the bonding layer 52 and the element layer 20 can be bonded to each other. Silicon oxide (SiOₓ) is preferred to silicon nitride (SiN) or the like because of being capable of forming a more planar surface. In the case where a layer formed on the surface of the element layer 20 and the bonding layer 52 are each formed of a layer containing silicon oxide (SiOₓ) and the planarity of the silicon oxide is increased, a hydroxyl group (OH group) on the surface of the silicon oxide formed on the surface of the element layer 20 and a hydroxyl group (OH group) on the surface of the silicon oxide of the bonding layer 52 are bonded to each other owing to the van der Waals force, and heat treatment performed later can generate a Si—O—Si bond and an H₂O molecule.

In FIG. 13B, as illustrated in FIG. 12B and FIG. 12C, the element layer 30B is bonded to the element layer 20 in a face-down manner. The element layer 20 includes the Si transistor M_{Si} and the electrode M_{CU} included in the arithmetic unit 21. The through electrode 54 provided in the element layer 61, the element layer 62, and the element layer 20 is provided to connect the electrode M_{CU} included in the element layer 61 and the electrode M_{CU} included in the element layer 20.

By increasing planarity of the bonding layer 52 or the like, bonding between the element layer 20 and the element layer 30B is possible in a range with an upper limit of 350° C. to 450° C. without exposure to high temperatures of 1000° C. or higher. That is, bonding between the element layer 20 and the element layer 30B is possible without exposure to high temperatures. Accordingly, variations in electrical characteristics of the OS transistor Mos caused by exposing the element layer 30B to high temperatures can be inhibited. In addition, since the Si transistor is not exposed to high temperatures in bonding between the element layer 20 and the element layer 30B, using a copper wiring is possible.

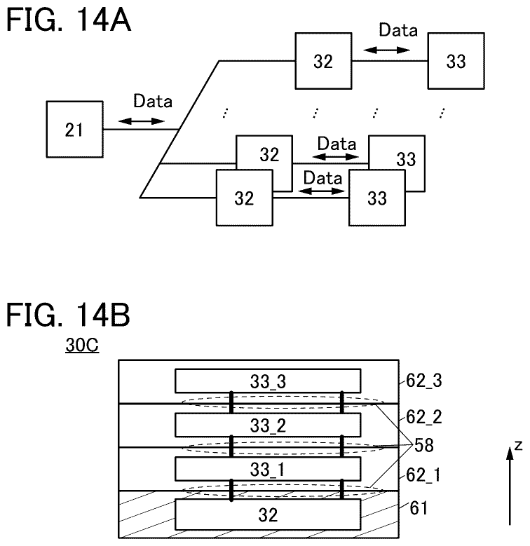

In the case where functional circuit units 32 having a function of an arithmetic unit such as a CPU and a GPU are dispersedly arranged in each of the element layers 30B_1 to 30B_n, input and output of data can be performed in parallel as illustrated in FIG. 14A. Thus, the arithmetic operations of the functional circuit units 32 can be performed in parallel, the semiconductor device 10E can have higher functionality.

Although a single element layer is illustrated as the element layer 62 in FIG. 12A, a plurality of element layers 62 can be stacked over the element layer 61. FIG. 14B illustrates a structure example of the element layer in this case. In the element layers 62 (62_1 to 62_3) stacked as in the element layer 30C illustrated in FIG. 14B, the electrodes 58 for electrically connecting the memory units 33 (the memory units 33_1 to 33_3) of each layers and the functional circuit units 32 are the electrodes 58 described with reference to FIG. 11B. The electrode 58 is a wiring that can be formed in a manner similar to that of the layer where OS transistors are provided. Thus, the number of wirings (the number of signal lines) of the memory unit 33 provided in the element layer 62 and the functional circuit unit 32 provided in the element layer 61 can be increased.

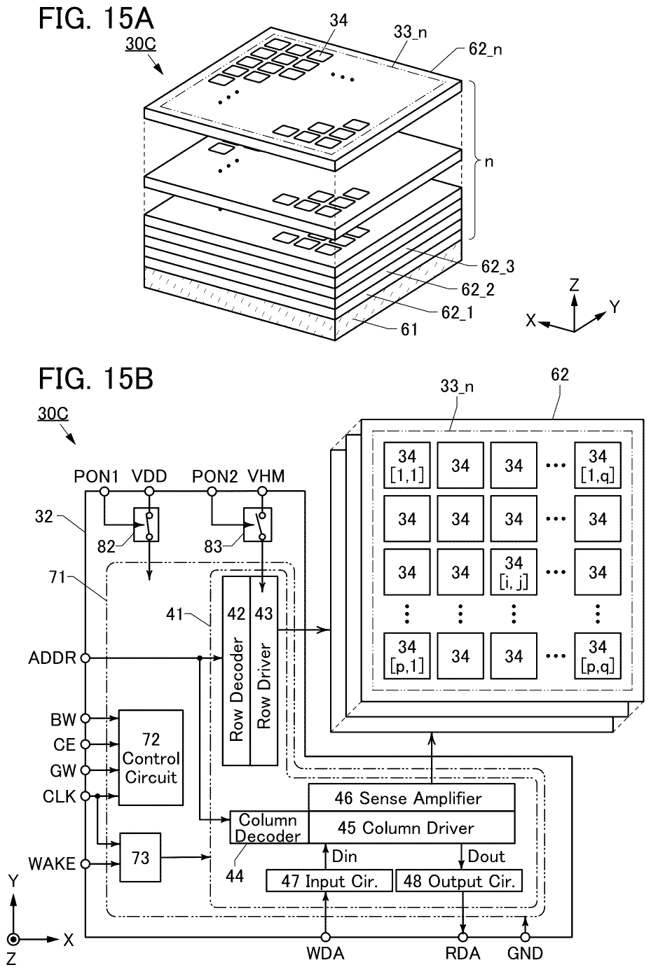

Note that in the structure example of FIG. 14B, the functional circuit unit 32 is preferably used as a driver circuit of a memory cell included in the stacked memory units 33 (the memory units 33_1 to 33_3). A specific example in the case where the functional circuit unit 32 is used as the driver circuit of the memory unit 33 is described with reference to FIG. 15A and FIG. 15B.

FIG. 15A is a schematic perspective view of the element layer 30C of one embodiment of the present invention. FIG. 15B is a block diagram of the element layer 30C of one embodiment of the present invention.

The element layer 30C illustrated in FIG. 15A and FIG. 15B includes the element layer 61 and n element layers 62 (n is an integer greater than or equal to 1). The element layers 62 include the memory unit 33 (the memory units 33_1 to 33_n). The memory unit 33 includes a plurality of memory cells 34.

The n element layers 62 are provided over the element layer 61. Providing the n element layers 62 over the element layer 61 can reduce the area occupied by the element layer 30C. Furthermore, memory capacity per unit area can be increased.

The functional circuit unit 32 functioning as a driver circuit included in the element layer 61 includes a PSW 82 (power switch), a PSW 83, and a peripheral circuit 71. The peripheral circuit 71 includes a peripheral circuit 41, a control circuit 72, and a voltage generation circuit 73.

In the element layer 30C, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. The signal PON1 and the signal PON2 may be generated in the control circuit 72.

The control circuit 72 is a logic circuit having a function of controlling the entire operation of the element layer 30C. For example, the control circuit performs a logical operation on the signal CE, the signal GW, and the signal BW to determine an operation mode (e.g., a writing operation or a reading operation) of the element layer 30C. Alternatively, the control circuit 72 generates a control signal for the peripheral circuit 41 so that the operation mode is executed.

The voltage generation circuit 73 has a function of generating a negative voltage. The signal WAKE has a function of controlling the input of the signal CLK to the voltage generation circuit 73. For example, when an H-level signal is supplied as the signal WAKE, the signal CLK is input to the voltage generation circuit 73, and the voltage generation circuit 73 generates a negative voltage.

The peripheral circuit 71 is a circuit for writing and reading data to/from the memory cells 34. The peripheral circuit 71 includes a row decoder 42 (Row Decoder), a column decoder 44 (Column Decoder), a row driver 43 (Row Decoder), a column driver 45 (Column Driver), an input circuit 47 (Input Cir.), an output circuit 48 (Output Cir.), and a sense amplifier 46 (Sense Amplifier).

The row decoder 42 and the column decoder 44 have a function of decoding the signal ADDR. The row decoder 42 is a circuit for addressing a row to be accessed, and the column decoder 44 is a circuit for addressing a column to be accessed. The row driver 43 has a function of selecting a wiring WWL (write word line) or a wiring RWL (read word line) specified by the row decoder 42. The column driver 45 has a function of writing data to the memory cells 34, a function of reading data from the memory cells 34, a function of retaining the read data, and the like. The column driver 45 has a function of selecting the wiring WBL (write bit line) and the wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 34. Data (Dout) read from the memory cells 34 by the column driver 45 is output to the output circuit 48. The output circuit 48 has a function of retaining Dout. The output circuit 48 also has a function of outputting Dout to the outside of the element layer 30C. Data output from the output circuit 48 is the signal RDA.

The PSW 82 has a function of controlling supply of VDD to the peripheral circuit 71. The PSW 83 has a function of controlling supply of VHM to the row driver 43. Here, in the element layer 30C, a high power supply voltage is VDD and a low power supply voltage is GND (a ground potential). In addition, VHM is high power supply voltage used to set the word line at a high level and is higher than VDD. The on/off of the PSW 82 is controlled by the signal PON1, and the on/off of the PSW 83 is controlled by the signal PON2. The number of power domains to which VDD is supplied is one in the peripheral circuit 71 in FIG. 15B but can be more than one. In that case, a power switch is provided for each power domain.

A structure example of the n element layers 62 will be described. Each of the n element layers 62 includes the memory unit 33. The memory unit 33 includes a plurality of memory cells 34. FIG. 15A and FIG. 15B illustrate an example in which the memory unit 33 includes the plurality of memory cells 34 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row” in some cases.

In FIG. 15B, the memory cell 34 provided in the first row and the first column is referred to as a memory cell 34[1,1], and the memory cell 34 provided in the p-th row and the q-th column is referred to as a memory cell 34[p,q]. In addition, the memory cell 34 provided in the i-th row and the j-th column (i is an integer greater than or equal to 1 and less than or equal to p. j is an integer greater than or equal to 1 and less than or equal to q.) is referred to as a memory cell 34[i,j].

In the case where the element layers 62 are stacked, it is preferable to arrange the wiring WBL and the wiring RBL in a direction perpendicular to the substrate surface. When the wiring WBL and the wiring RBL are provided in the direction perpendicular to the substrate surface, the signal transmission distance from the sense amplifier connected to the wiring WBL and the wiring RBL can be shortened and the resistance and parasitic capacitance of the wiring WBL and the wiring RBL can be significantly reduced. Thus, power consumption and signal delays can be reduced.

The configuration, structure, method, and the like described in this embodiment can be used in combination as appropriate with the configurations, structures, methods, and the like described in the other embodiments, an example, and the like.

### Embodiment 2

In this embodiment, a cross-sectional structure example of stacked element layers, which include OS transistors, applicable to a semiconductor device or the like is described. In this embodiment, an example of a schematic cross-sectional view that can be applied to a circuit structure such as a DOSRAM or a NOSRAM is described.

### <Structural Example 1 of DOSRAM>

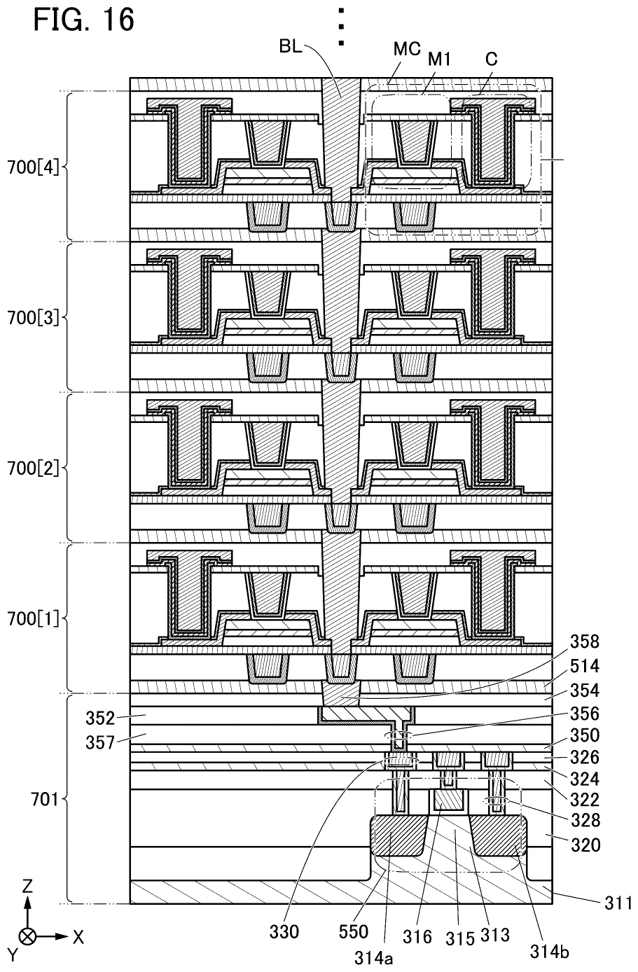

FIG. 16 illustrates a cross-sectional structure example of the case of using a DOSRAM circuit structure. In the example illustrated in FIG. 16, an element layer 700[1] to an element layer 700[4] are stacked over an element layer 701. The element layer 701 corresponds to, for example, the element layer 20 described in the above embodiment. The element layer 700 corresponds to, for example, the element layer 30 described in the above embodiment.

FIG. 16 illustrates a transistor 550 included in the element layer 701 as an example. The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

Note that the transistor 550 may be either a p-channel transistor or an n-channel transistor.

The low-resistance region 314a and the low-resistance region 314b include an element that imparts n-type conductivity, such as arsenic or phosphorus, or an element that imparts p-type conductivity, such as boron, in addition to the semiconductor material applied to the semiconductor region 313.

For the conductor 316 functioning as a gate electrode, a semiconductor material such as silicon including the element that imparts n-type conductivity, such as arsenic or phosphorus, or the element that imparts p-type conductivity, such as boron, or a conductive material such as a metal material, an alloy material, or a metal oxide material can be used.

The transistor 550 may be formed using an SOI (silicon on Insulator) substrate or the like.

The transistor 550 illustrated in FIG. 16 is an example and the structure is not limited thereto; an appropriate transistor can be used depending on a circuit structure, a driving method, or the like.

A wiring layer provided with an interlayer film, a wiring, a plug, and the like may be provided between the element layer 701 and the element layers 700 or between a k-th element layer 700 and a (k+1)-th element layer 700. Note that in this embodiment and the like, the k-th element layer 700 is referred to as an element layer 700[k], and the (k+1)-th element layer 700 is referred to as an element layer 700[k+1], in some cases. Here, k is an integer greater than or equal to 1 and less than or equal to N. In addition, in this embodiment and the like, the solutions of “k+α (α is an integer greater than or equal to 1)” and “k-α” are each an integer greater than or equal to 1 and less than or equal to N.

A plurality of wiring layers can be provided in accordance with the design. Furthermore, in this specification and the like, a wiring and a plug electrically connected to the wiring may be a single component. That is, part of a conductor functions as a wiring in some cases and part of a conductor functions as a plug in other cases.

For example, an insulator 320, an insulator 322, an insulator 324, and an insulator 326 are sequentially stacked and provided over the transistor 550 as interlayer films. In addition, an conductor 328 or the like is embedded in the insulator 320 and the insulator 322. Furthermore, a conductor 330 or the like is embedded in the insulator 324 and the insulator 326. Note that the conductor 328 and the conductor 330 each function as a contact plug or a wiring.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator functioning as an interlayer film may function as a planarization film that covers an uneven shape thereunder. For example, a top surface of the insulator 320 may be planarized by planarization treatment using a chemical mechanical polishing (CMP) method to increase planarity.

In addition, for the insulator 324, it is preferable to use a film having a barrier property that prevents diffusion of hydrogen, impurities, or the like from the substrate 311, the transistor 550, or the like into a region in the element layer 700[1] to the element layer 700[4] where the transistor 500 is provided.

For the film having a barrier property against hydrogen, for example, silicon nitride formed by a CVD method can be used. Here, diffusion of hydrogen into a semiconductor element including an oxide semiconductor, such as the transistor 500, degrades the characteristics of the semiconductor element in some cases. Thus, a film that inhibits diffusion of hydrogen is preferably provided between the transistor 500 and the transistor 550. The film that inhibits diffusion of hydrogen is specifically a film from which a small amount of hydrogen is released.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with a lower permittivity is used for an interlayer film, parasitic capacitance generated between wirings can be reduced.

A wiring layer may be provided over the insulator 326 and the conductor 330. For example, in FIG. 16, an insulator 350, an insulator 357, an insulator 352, and the insulator 354 are stacked in this order over the insulator 326 and the conductor 330. Furthermore, the conductor 356 is formed in the insulator 350, the insulator 357, and the insulator 352. The conductor 356 functions as a contact plug or a wiring.

As a material for each of the plugs and wirings (the conductor 328, the conductor 330, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulator 514 included in the element layer 700[1] is provided over the insulator 354. In addition, a conductor 358 is embedded in the insulator 514 and the insulator 354. The conductor 358 functions as a contact plug or a wiring. For example, the bit line BL and the transistor 550 are electrically connected to each other through the conductor 358, the conductor 356, the conductor 330, and the like.

For example, the insulator 350 is preferably formed using an insulator having a barrier property against hydrogen, like the insulator 324. The conductor 356 preferably includes a conductor having a barrier property against hydrogen. The conductor having a barrier property against hydrogen is formed particularly in an opening portion of the insulator 350 having a barrier property against hydrogen. With this configuration, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. In addition, by stacking tantalum nitride and tungsten, which has high conductivity, diffusion of hydrogen from the transistor 550 can be inhibited while the conductivity as a wiring is kept. In that case, a configuration where a tantalum nitride layer having a barrier property against hydrogen is in contact with the insulator 350 having a barrier property against hydrogen is preferable.

In the example illustrated in FIG. 16, two memory cells MC are electrically connected to one bit line BL in each of the element layer 700[1] to the element layer 700[4]. The memory cell MC illustrated in FIG. 16 includes a transistor M1 and a capacitor C. As the transistor M1, an OS transistor can be used.

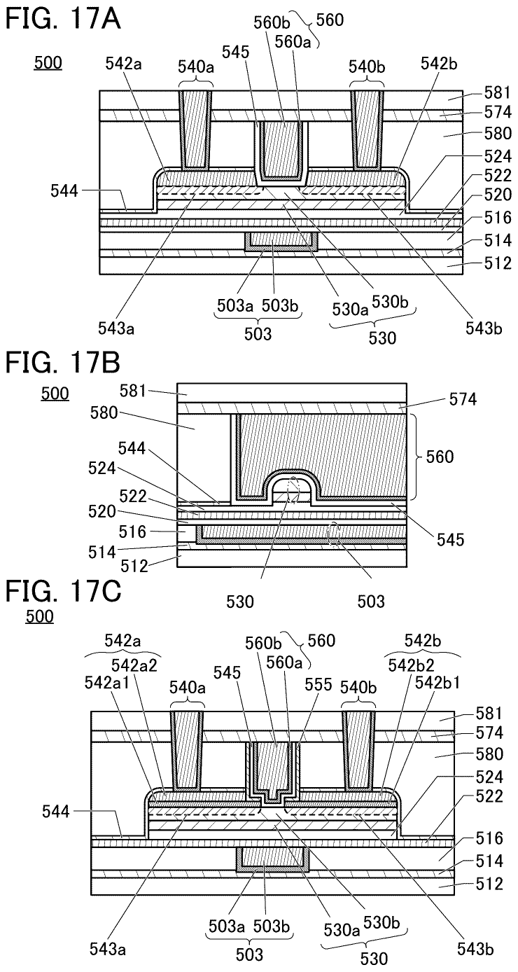

Here, OS transistors are described with reference to FIG. 17A to FIG. 17C. FIG. 17A and FIG. 17B are schematic cross-sectional views of the transistor 500 that can be applied to the transistor M1.

As illustrated in FIG. 17A and FIG. 17B, the transistor 500 includes a conductor 503 placed to be embedded in the insulator 514 and an insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with a region between the conductor 542a and the conductor 542b, an insulator 545 placed on a bottom surface and a side surface of the opening, and a conductor 560 placed on the formation surface of the insulator 545.

As illustrated in FIG. 17A and FIG. 17B, an insulator 544 is preferably placed between the insulator 580 and the oxide 530a, the oxide 530b, the conductor 542a, and the conductor 542b. In addition, as illustrated in FIG. 17A and FIG. 17B, the conductor 560 preferably includes a conductor 560a provided inside the insulator 545 and a conductor 560b embedded inside the conductor 560a. Moreover, as illustrated in FIG. 17A and FIG. 17B, an insulator 574 is preferably placed over the insulator 580, the conductor 560, and the insulator 545.

Note that in this specification and the like, the oxide 530a and the oxide 530b are collectively referred to as an oxide 530 in some cases.

Note that the transistor 500 is illustrated to have a structure in which two layers, the oxide 530a and the oxide 530b, are stacked in the region where the channel is formed and its vicinity; however, the present invention is not limited thereto. For example, a single layer of the oxide 530b or a stacked-layer structure of three or more layers may be provided.

In addition, although the conductor 560 has a stacked-layer structure of two layers in the transistor 500, the present invention is not limited thereto. For example, the conductor 560 may have a single-layer structure or a stacked-layer structure of three or more layers. The transistor 500 illustrated in FIG. 17A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and higher integration of the semiconductor device can be achieved.

In addition, since the conductor 560 is formed in the region between the conductor 542a and the conductor 542b in a self-aligned manner, the conductor 560 does not include a region overlapping with the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. The conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to overlap with the oxide 530 and the conductor 560. Accordingly, when a potential is applied to the conductor 560 and the conductor 503, an electric field generated from the conductor 560 and an electric field generated from the conductor 503 are connected, thereby covering the channel formation region in the oxide 530.

In this specification and the like, a transistor structure where a channel formation region is electrically surrounded by an electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. In this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Accordingly, the density of current flowing through the transistor can be increased, which can be expected to increase the on-state current of the transistor or increase the field-effect mobility of the transistor.

In addition, the conductor 503 has a configuration similar to that of the conductor 518; a conductor 503a is formed in contact with an inner wall of an opening in the insulator 514 and the insulator 516, and a conductor 503b is formed on the inner side. Note that although the conductor 503a and the conductor 503b are stacked in the transistor 500, the present invention is not limited thereto. For example, the conductor 503 may have a single-layer structure or a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities do not easily pass) is preferably used. Alternatively, it is preferable to use a conductive material that has a function of inhibiting diffusion of oxygen (e.g., at least one of an oxygen atom, an oxygen molecule, and the like) (through which oxygen does not easily pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In the case where the conductor 503 also functions as a wiring, a conductive material with high conductivity that includes tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region containing excess oxygen (also referred to as an “excess-oxygen region”) is preferably formed in the insulator 524. When such an insulator containing excess oxygen is provided in contact with the oxide 530, oxygen vacancies (also referred to as Vo) in the oxide 530 can be reduced and the reliability of the transistor 500 can be increased. In the case where hydrogen enters the oxygen vacancies in the oxide 530, such defects (hereinafter, sometimes referred to as VoH) serve as donors and generate electrons serving as carriers in some cases. In some cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in the oxide semiconductor is easily transferred by a stress such as heat or an electric field; thus, a large amount of hydrogen in the oxide semiconductor might reduce the reliability of the transistor. In one embodiment of the present invention, VoH in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose VoH is sufficiently reduced. When an oxide semiconductor with a sufficiently reduced amount of impurities such as VoH is used for the channel formation region of the transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the oxide 530 or an insulator in the vicinity of the oxide 530 in some cases. In other cases, part of hydrogen is generated by the conductors 542a and 542b.

In addition, for the microwave treatment, for example, it is suitable to use an apparatus including a power supply that generates high-density plasma or an apparatus including a power supply that applies RF to a substrate side. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. Pressure in the microwave treatment is higher than or equal to 133 Pa, preferably higher than or equal to 200 Pa, further preferably higher than or equal to 400 Pa. Moreover, as a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In the fabrication process of the transistor 500, it is suitable to perform the heat treatment with the surface of the oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (Vo). The heat treatment may be performed under reduced pressure. Alternatively, the heat treatment may be performed in such a manner that heat treatment is performed in a nitrogen gas or inert gas atmosphere, and then heat treatment is performed in an atmosphere including an oxidizing gas at higher than or equal to 10 ppm, higher than or equal to 1%, or higher than or equal to 10% in order to compensate for released oxygen. Alternatively, heat treatment may be performed in an atmosphere including an oxidizing gas at higher than or equal to 10 ppm, higher than or equal to 1%, or higher than or equal to 10%, and then another heat treatment may be successively performed in a nitrogen gas or inert gas atmosphere.

Note that oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen does not easily pass).

The insulator 522 preferably has a function of inhibiting diffusion of oxygen, impurities, or the like, in which case diffusion of oxygen included in the oxide 530 to the insulator 520 side is prevented. Furthermore, the conductor 503 can be inhibited from reacting with oxygen included in the insulator 524, the oxide 530, or the like.

For the insulator 522, a single layer or stacked layers of an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and higher integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (through which oxygen does not easily pass). Aluminum oxide, hafnium oxide, an oxide including aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, the insulator may be subjected to nitriding treatment. Silicon oxide, silicon oxynitride, or silicon nitride may be stacked over the insulator.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and high relative permittivity.

Note that the transistor 500 in FIG. 17A and FIG. 17B includes the insulator 520, the insulator 522, and the insulator 524 as the second gate insulating film having a three-layer structure; however, the second gate insulating film may have a single-layer structure or a stacked-layer structure of two layers or four or more layers. In that case, without limitation to a stacked-layer structure formed of the same material, a stacked-layer structure formed of different materials may be employed.

In the transistor 500, a metal oxide functioning as an oxide semiconductor is used as the oxide 530 including the channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap of preferably 2 eV or more, further preferably 2.5 eV or more. The use of a metal oxide having such a wide bandgap can reduce the off-state current of the transistor.

When the oxide 530 includes the oxide 530a under the oxide 530b, it is possible to inhibit diffusion of impurities into the oxide 530b from the components formed below the oxide 530a.

The oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element Min the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a bonding portion of the oxide 530a and the oxide 530b. In other words, the energy level of the conduction band minimum at the bonding portion of the oxide 530a and the oxide 530b continuously changes or is continuously connected. To change the energy level gradually, the density of defect states in a mixed layer formed at the interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including the above metal element; an alloy including a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 17A, they may have a stacked-layer structure of two or more layers. For example, it is preferable to stack a tantalum nitride film and a tungsten film. Alternatively, a titanium film and an aluminum film may be stacked. Alternatively, a two-layer configuration where an aluminum film is stacked over a tungsten film, a two-layer configuration where a copper film is stacked over a copper-magnesium-aluminum alloy film, a two-layer configuration where a copper film is stacked over a titanium film, or a two-layer configuration where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

As illustrated in FIG. 17A, a region 543a and a region 543b are sometimes formed as low-resistance regions at the interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that includes the metal included in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator including an oxide of one or both of aluminum and hafnium, such as aluminum oxide, hafnium oxide, or an oxide including aluminum and hafnium (hafnium aluminate), as the insulator 544. In particular, hafnium aluminate has higher heat resistance than a hafnium oxide film. Thus, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

The insulator 544 can inhibit impurities such as water and hydrogen included in the insulator 580 from diffusing into the oxide 530b. Furthermore, oxidation of the conductors 542a and 542b due to excess oxygen included in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide including excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 functioning as the first gate electrode has a two-layer structure in FIG. 17A and FIG. 17B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be applied to the oxide 530 can be used. In that case, when the conductor 560b is formed by a sputtering method, the conductor 560a can have a reduced electrical resistance value to be a conductor. Such a conductor can be referred to as an OC (Oxide Conductor) electrode.

A conductive material containing tungsten, copper, or aluminum as its main component is preferably used for the conductor 560b. The conductor 560b also functions as a wiring and thus a conductor having high conductivity is preferably used. For example, a conductive material containing tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide including one kind or two or more kinds selected from hafnium, aluminum, gallium, yttrium, zirconium, tungsten, titanium, tantalum, nickel, germanium, magnesium, or the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The configurations of the conductor 540a and the conductor 540b are similar to those of a conductor 546 and a conductor 548 that will be described later.

An insulator 582 is provided over the insulator 581. A substance having a barrier property against oxygen, hydrogen, or the like is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after a manufacturing process of the transistor. In addition, release of oxygen from the oxide included in the transistor 500 can be inhibited. Thus, aluminum oxide is suitably used for a protective film of the transistor 500.

An insulator 586 is provided over the insulator 582. For the insulator 586, a material similar to that for the insulator 320 can be used. Furthermore, when a material with comparatively low permittivity is applied to these insulators, parasitic capacitance generated between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to a capacitor 600, the transistor 500, or the transistor 550. The conductor 546 and the conductor 548 can be provided using materials similar to those for the conductor 328 and the conductor 330.

In addition, after the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the fabrication steps of the transistor 500. Note that the insulator having a high barrier property against hydrogen or water is formed using a material similar to that for the insulator 522 or the insulator 514, for example.

Note that the transistor that can be used in the present invention is not limited to the transistor 500 illustrated in FIG. 17A and FIG. 17B. For example, the transistor 500 having a structure illustrated in FIG. 17C may be used. The transistor 500 illustrated in FIG. 17C is different from the transistor illustrated in FIG. 17A and FIG. 17B in that an insulator 555 is used and that the conductor 542a (a conductor 542a1 and a conductor 542a2) and the conductor 542b (a conductor 542b1 and a conductor 542b2) each have a stacked-layer structure.

The conductor 542a has a stacked-layer structure of the conductor 542al and the conductor 542a2 over the conductor 542a1, and the conductor 542b has a stacked-layer structure of the conductor 542b1 and the conductor 542b2 over the conductor 542b1. The conductor 542a1 and the conductor 542b1 in contact with the oxide 530b are preferably conductors that are less likely to be oxidized, such as a metal nitride. Thus, excessive oxidation of the conductor 542a and the conductor 542b due to oxygen included in the oxide 530b can be prevented. In addition, the conductor 542a2 and the conductor 542b2 are preferably conductors that have higher conductivity than the conductor 542a1 and the conductor 542b1, such as metal layers. This allows the conductor 542a and the conductor 542b to function as wirings or electrodes having high conductivity. In this manner, it is possible to provide a semiconductor device in which the conductor 542a and the conductor 542b that function as wirings or electrodes are provided in contact with the top surface of the oxide 530 functioning as an active layer.

A metal nitride is preferably used for the conductors 542a1 and 542b1. For example, a nitride including tantalum, a nitride including titanium, a nitride including molybdenum, a nitride including tungsten, a nitride including tantalum and aluminum, a nitride including titanium and aluminum, or the like is preferably used. In one embodiment of the present invention, a nitride containing tantalum is particularly preferable. For another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

In addition, the conductor 542a2 and the conductor 542b2 preferably have higher conductivity than the conductor 542a1 and the conductor 542b1. For example, film thickness of the conductor 542a2 and the conductor 542b2 is preferably larger than film thickness of the conductor 542a1 and the conductor 542b1. As each of the conductor 542a2 and the conductor 542b2, a conductor that can be used as the conductor 560b is used. With such a structure, resistance of the conductor 542a2 and the conductor 542b2 can be reduced.

For example, tantalum nitride or titanium nitride can be used for the conductor 542a1 and the conductor 542b1, and tungsten can be used for the conductor 542a2 and the conductor 542b2.

As illustrated in FIG. 17C, in a cross-sectional view in the channel length direction of the transistor 500, the distance between the conductor 542a1 and the conductor 542b1 is shorter than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 555 is preferably an insulator that is not easily oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is preferably an inorganic insulator that is not easily oxidized because it is exposed to an oxidizing atmosphere. In addition, the insulator 555 is preferably an inorganic insulator that does not easily oxidize the conductors 542a2 and 542b2 because it is in contact with the conductor 542a2 and the conductor 542b2. Thus, an insulating material having a barrier property against oxygen is preferably used for the insulator 555. For example, silicon nitride can be used for the insulator 555.

The transistor 500 illustrated in FIG. 17C is formed by formation of an opening in the insulator 580 and the insulator 544, formation of the insulator 555 in contact with sidewalls of the opening, and division of the conductor 542a1 and the conductor 542b1 with the use of a mask. Here, the opening overlaps with a region between the conductor 542a2 and the conductor 542b2. In addition, parts of the conductor 542a1 and the conductor 542b1 are formed to protrude inside the opening. Thus, the insulator 555 is in contact with, in the opening, a top surface of the conductor 542a1, a top surface of the conductor 542b1, a side surface of the conductor 542a2, and a side surface of the conductor 542b2. The insulator 545 is in contact with the top surface of the oxide 530 in a region between the conductor 542a1 and the conductor 542b1.

After the conductor 542a1 and the conductor 542b1 are divided, heat treatment is preferably performed in an oxygen-containing atmosphere before deposition of the insulator 545. Thus, oxygen can be supplied to the oxide 530a and the oxide 530b to reduce oxygen vacancies. In addition, when the insulator 555 is formed in contact with the side surface of the conductor 542a2 and the side surface of the conductor 542b2, the conductor 542a2 and the conductor 542b2 can be prevented from being excessively oxidized. Consequently, electrical characteristics and reliability of the transistor can be improved. In addition, variations in electrical characteristics of transistors formed over the same substrate can be reduced.

In addition, in the transistor 500, as illustrated in FIG. 17C, the insulator 524 may be formed into an island shape. Here, the insulator 524 may be formed such that the side end portion thereof is substantially aligned with the side end portion of the oxide 530.

In addition, in the transistor 500, as illustrated in FIG. 17C, a structure may be employed in which the insulator 522 is in contact with the insulator 516 and the conductor 503. In other words, a structure where the insulator 520 illustrated in FIG. 17A and FIG. 17B is not provided may be employed.

With the use of this configuration, a semiconductor device using a transistor including an oxide semiconductor can be miniaturized or highly integrated.

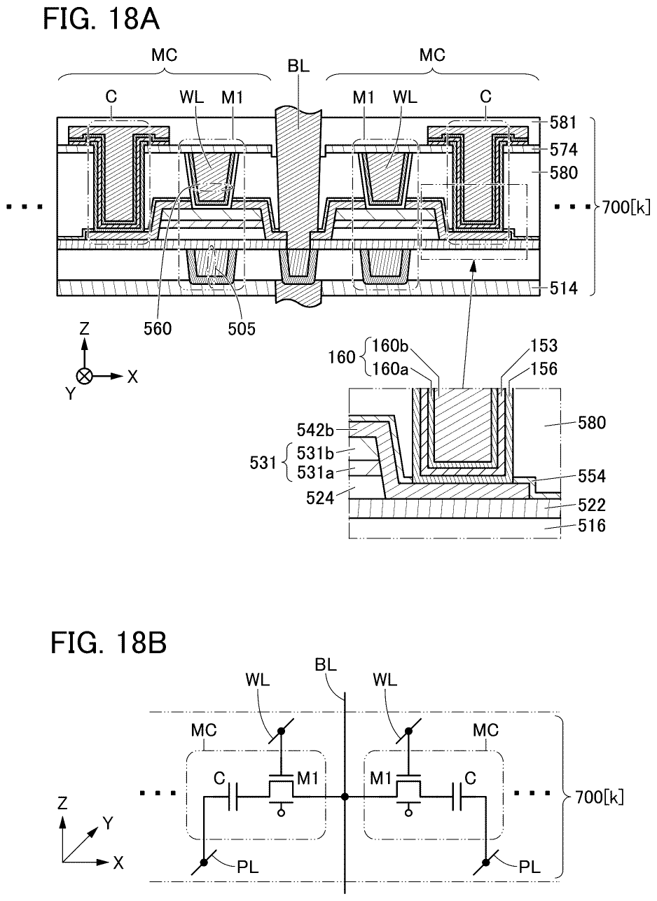

Next, FIG. 18A illustrates a cross-sectional structure example of the element layer 700[k] that can be applied to the element layers 700[1] to 700[4] illustrated in FIG. 16. FIG. 18B is an equivalent circuit diagram of FIG. 18A. FIG. 18A illustrates an example where two memory cells MC are electrically connected to one bit line BL.

The transistor M1 is a modification example of the transistor 500. Specifically, the transistor M1 is different from the transistor 500 in that the conductor 542a and the conductor 542b extend beyond the end portion of a metal oxide 531 (a metal oxide 531a and a metal oxide 531b).

The memory cell MC illustrated in FIG. 18A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. Furthermore, the conductor 160 is electrically connected to a wiring PL (not illustrated in FIG. 18A).

The capacitor C is formed in an opening portion that is provided by removal of part of the insulator 574, part of the insulator 580, and part of an insulator 554. The conductor 156, the insulator 580, and the insulator 554 are formed along the side surface of the opening portion, and thus are preferably deposited by an ALD method, a CVD method, or the like.

The conductor 156 and the conductor 160 may be formed using a conductor that can be used for a conductor 505 or the conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

As the insulator 153, an insulator of a high permittivity (high-k) material (material with a high relative permittivity) is preferably used. As the insulator of a high permittivity material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, or nitride may contain silicon. Insulating layers each formed of any of the above-described materials can be stacked to be used. As the insulator 153, a stacked-layer structure of three layers of zirconium oxide, aluminum oxide, and zirconium oxide is given for example. Note that the stacked-layer structure of three-layer stacked structure of zirconium oxide, aluminum oxide, and zirconium oxide is referred to as ZAZ in some cases.

As the insulator of high permittivity material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high permittivity material allows the insulator 153 to be thick enough to inhibit an off-state current and a sufficiently high capacitance of the capacitor C to be ensured.

It is preferable to use stacked insulating layers each formed of any of the above-described materials. A stacked-layer structure using a high permittivity material and a material having higher dielectric strength than the high permittivity material is preferably used. For example, as the insulator 153, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor C.

Alternatively, a material that can have ferroelectricity may be used for the insulating layer 153. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium atom to the element JI can be set as appropriate; the atomic ratio of hafnium atom to the element J1 is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium atom to the element J2 can be set as appropriate; the atomic ratio of zirconium atom to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

### <Structure Example of NOSRAM>

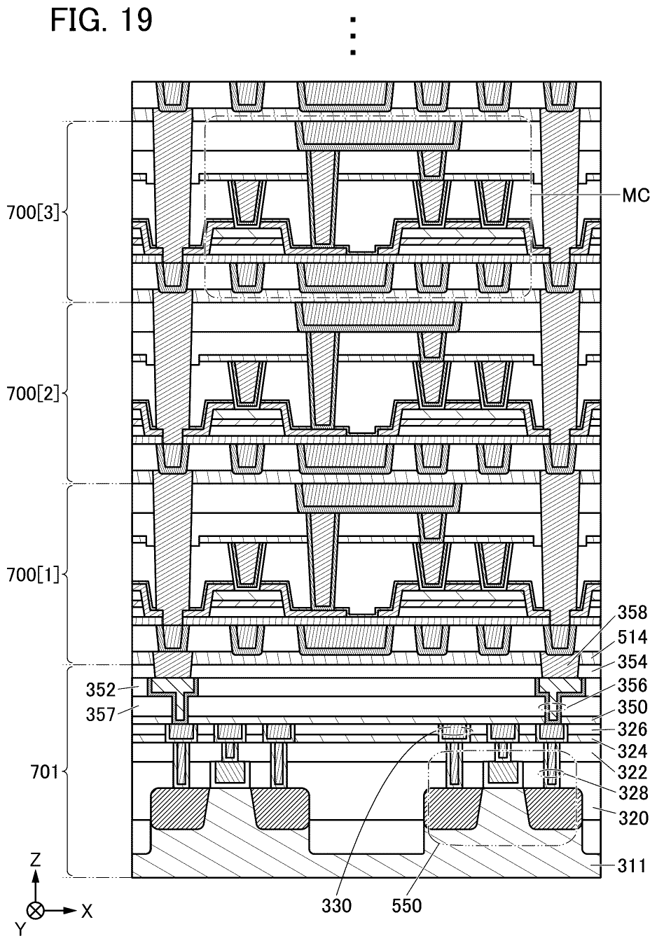

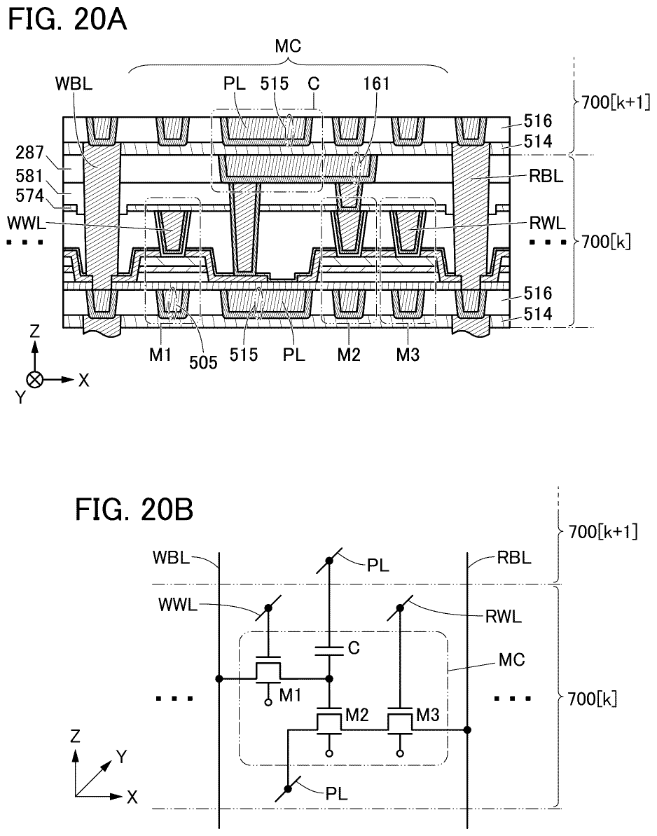

FIG. 19 illustrates a cross-sectional structure example of the case of using a NOSRAM memory cell circuit structure. Note that FIG. 19 is also a modification example of FIG. 16. FIG. 20A illustrates a cross-sectional structure example of the element layer 700[k]. In addition, FIG. 20B illustrates an equivalent circuit diagram of FIG. 20A.

The memory cell MC illustrated in FIG. 19 and FIG. 20A includes the transistor M1, a transistor M2, and a transistor M3 over the insulator 514. In addition, a conductor 515 is provided over the insulator 514. The conductor 515 and the conductor 505 can be concurrently formed using the same material in the same step.

The transistor M2 and the transistor M3 illustrated in FIG. 19 and FIG. 20A share one island-shaped metal oxide 531. In other words, a part of the one island-shaped metal oxide 531 functions as a channel formation region of the transistor M2, and another part thereof functions as a channel formation region of the transistor M3. Furthermore, a source of the transistor M2 and a drain of the transistor M3 are shared, or a drain of the transistor M2 and a source of the transistor M3 are shared. Thus, the area occupied by the transistor is smaller than that of the case where the transistor M2 and the transistor M3 are independently provided.

In the memory cell MC illustrated in FIG. 19 and FIG. 20A, an insulator 287 is provided over the insulator 581, and a conductor 161 is embedded in the insulator 287. Furthermore, the insulator 514 of an element layer 700[k+1] is provided over the insulator 287 and the conductor 161.

In FIG. 19 and FIG. 20A, the conductor 515 of the element layer 700[k+1] functions as one terminal of the capacitor C, the insulator 514 of the element layer 700[k+1] functions as a dielectric of the capacitor C, and the conductor 161 functions as the other terminal of the capacitor C. Furthermore, the other of a source and a drain of the transistor M1 is electrically connected to the conductor 161 through a contact plug, and a gate of the transistor M2 is electrically connected to the conductor 161 through another contact plug.

### <Structure Example 2 of DOSRAM>

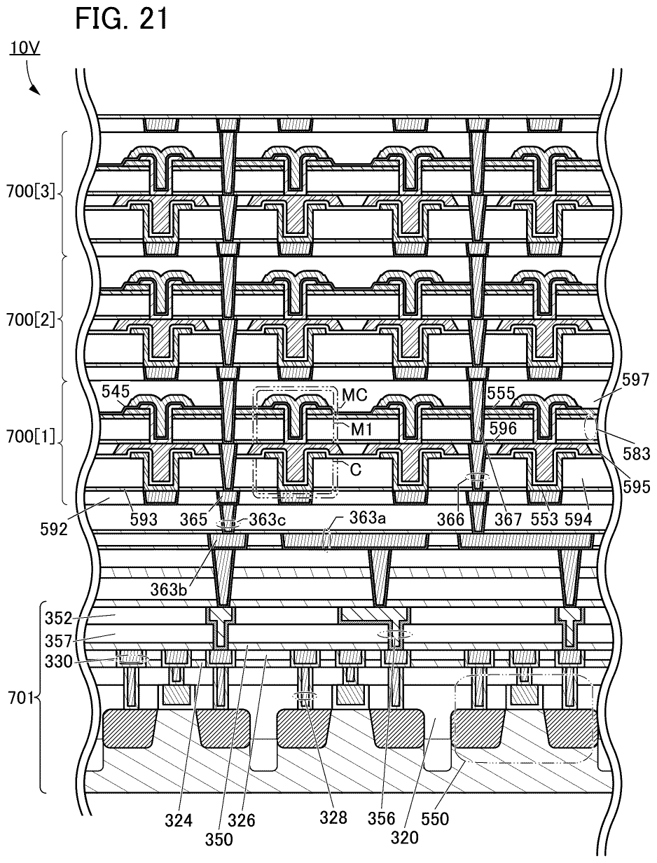

Next, FIG. 21 illustrates a cross-sectional structure example of stacked element layers including OS transistors, which can be applied to the semiconductor device of one embodiment of the present invention or the like, and is different from those in FIG. 16 to FIG. 20A and FIG. 20B. In a semiconductor device 10V illustrated in FIG. 21, the capacitor C is provided below the transistor M1 in the memory cell MC provided in the element layer 700[1] to the element layer 700[3] illustrated in FIG. 21.

In FIG. 21, each of a plurality of element layers 700 includes a plurality of memory cells MC. In the memory cell MC illustrated in FIG. 21, the transistor M1 and the capacitor C are illustrated.

A conductor 363a, a conductor 363b, and a conductor 363c are embedded in an interlayer film between the element layer 701 and the element layer 700. In each of the plurality of element layers 700, a conductor 365 is embedded in an insulator 592 described later. Also, in each of the plurality of element layers 700, the conductor 366 is embedded in an insulator 593, an insulator 594, an insulator 553, and an insulator 595 that are described later. Furthermore, in each of the plurality of element layers 700, a conductor 367 is embedded in an insulator 596, an insulator 583, the conductor 542b, the insulator 555, and an insulator 597 that are described later. The conductor 363a, the conductor 363b, the conductor 363c, the conductor 365, the conductor 366, and the conductor 367 each function as a via hole, a contact plug, or a wiring.

Next, a structure example of the memory cell MC included in each of the plurality of element layers 700 of the semiconductor device 10V in FIG. 21 is described.

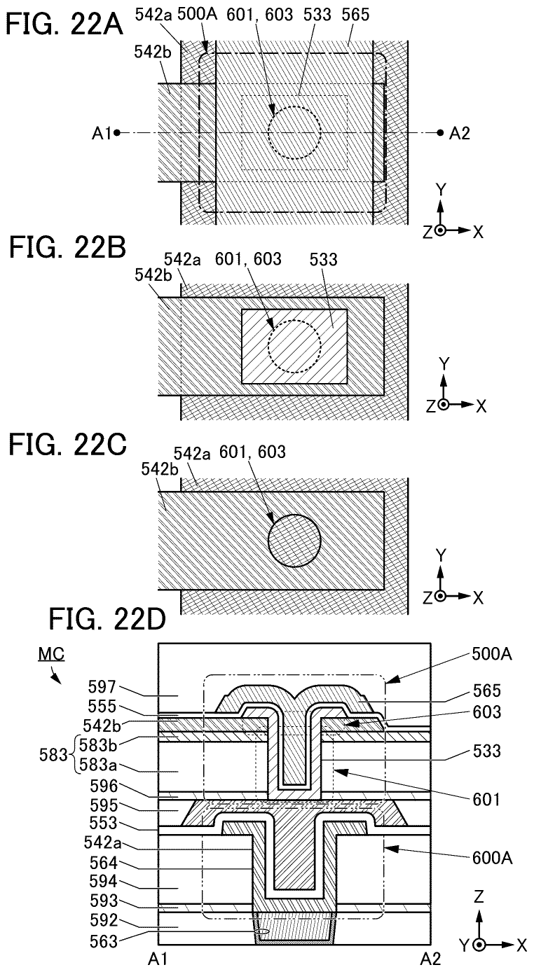

FIG. 22A is a plan view illustrating a structure example of the memory cell MC included in each of the plurality of element layers 700 of the above-described semiconductor device 10V and the periphery of the memory cell MC. Note that in FIG. 22A to FIG. 22D, a transistor 500A corresponds to the transistor M1 in FIG. 21, and a capacitor 600A corresponds to the capacitor C in FIG. 21. FIG. 22D is a cross-sectional view taken along a dashed-dotted line A1-A2 in FIG. 22A. Note that in FIG. 22A, some components of the transistor M1, such as an insulator, are not illustrated. Also in the other plan views of the transistor, some components such as an insulator are not illustrated.

The capacitor 600A includes the insulator 593, the insulator 594, the insulator 553, the insulator 595, a conductor 563, a conductor 564, and the conductor 542a, for example.

The conductor 563 is embedded in the conductor 563. The conductor 563 can be, for example, the wiring PL extending in the Y direction.

The insulator 593 and the insulator 594 are formed in this order over the insulator 592 and the conductor 563, for example. An opening is provided in a region of the insulator 593 and a region of the insulator 594 which overlap with the conductor 563. The conductor 564 is formed on the bottom surface (over the conductor 563) and the side surface of the opening. Note that in FIG. 22D, the conductor 564 is formed also on the top surface of the insulator 594. The insulator 553 is formed over the insulator 594 and the conductor 564. The conductor 542a is formed to cover a region of the insulator 553 that overlaps with the conductor 564. The insulator 595 is formed over the conductor 542a and the insulator 553. Note that the top surface of the insulator 595 and the top surface of the conductor 542a are preferably substantially level with each other. Therefore, the insulator 595 and the conductor 542a are preferably planarized by planarization treatment using a chemical mechanical polishing (CMP) method or the like, for example.

The conductor 564 corresponds to one of a pair of terminals of the capacitor 600A, for example. The conductor 542a corresponds to the other of the pair of terminals of the capacitor 600A, for example.

The insulator 553 functions as a dielectric sandwiched between a pair of terminals of the capacitor 600A, for example.

The transistor 500A is provided above the conductor 542a and the insulator 595 of the capacitor 600A.

In the transistor 500A, the channel length direction is not substantially parallel to the substrate 311 but along the side surface of a later-described opening provided in the insulator 583.

The transistor 500A includes the conductor 542a functioning as one of the source electrode and the drain electrode, the conductor 542b functioning as the other of the source electrode and the drain electrode, a metal oxide 533, the insulator 555, and a conductor 565 functioning as a gate electrode, for example. FIG. 22A illustrates an example in which the conductor 542b extends in the direction perpendicular to the conductor 542a and the conductor 565. Note that as described above, the conductor 542a functions also as the other of the pair of electrodes of the capacitor 600A.

For the metal oxide 533, for example, the material that can be applied to the oxide 530 included in the above-described transistor 500 can be used.

In FIG. 22A and FIG. 22D of this embodiment, the direction in which the conductor 542b extends is referred to as the X direction. The direction perpendicular to the X direction and parallel to the top surface of the conductor 563, for example, is referred to as the Y direction, and the direction perpendicular to the top surface of the conductor 563 is referred to as the Z direction. The definition of the X direction, the Y direction, and the Z direction applies to the following drawings in some cases. The X direction, the Y direction, and the Z direction can be perpendicular to each other. In the description of a plan view in this specification and the like, the X direction may be referred to as the right side or the left side and the Y direction may be referred to as the upper side or the lower side. The right side may be rephrased as the X direction, the left side may be rephrased as the-X direction, the upper side may be rephrased as the Y direction, and the lower side may be rephrased as the-Y direction in some cases.

The conductor 542a functions as one of the source electrode and the drain electrode of the transistor 500A. The conductor 542b functions as the other of the source electrode and the drain electrode of the transistor 500A. The insulator 555 functions as a gate insulating layer of the transistor 500A. The conductor 565 functions as the gate electrode of the transistor 500A.

In the metal oxide 533 between the source electrode and the drain electrode, the whole region overlapping with the gate electrode with the gate insulating layer therebetween functions as the channel formation region. The metal oxide 533 including a region functioning as the channel formation region is referred to as a semiconductor layer in some cases. In the metal oxide 533, a region in contact with the source electrode functions as a source region, and a region in contact with the drain electrode functions as a drain region.

The insulator 596 is provided over the insulator 595 and the conductor 542a. The insulator 596 can have a function of an interlayer insulating layer. The interlayer insulating layer here can be a barrier insulating film that inhibits diffusion of impurities such as water and hydrogen (e.g., one or both of a hydrogen atom and a hydrogen molecule).

The insulator 583 (an insulator 583a and an insulator 583b) is provided over the insulator 596, and the conductor 542b is provided over the insulator 583. The insulator 583 can have a function of an interlayer insulating layer. The interlayer insulating layer here can be an interlayer film for separation of the source electrode and the gate electrode in 500A.

An oxide or an oxynitride is preferably used as the insulator 583a, for example. The insulator 583a is preferably formed using a film from which oxygen is released by heating. As the insulator 583a, silicon oxide or silicon oxynitride can be suitably used, for example. Oxygen release from the insulator 583a enables oxygen supply from the insulator 583a to the metal oxide 533. When oxygen is supplied from the insulator 583a to the metal oxide 533, in particular, the channel formation region of the metal oxide 533, oxygen vacancies in the metal oxide 533 and hydrogen that enters the oxygen vacancies can be reduced. Consequently, the transistor 500A with favorable electrical characteristics and high reliability can be obtained.

The insulator 583b preferably includes a region containing more nitrogen than the insulator 583a, for example. For example, silicon nitride or silicon nitride oxide can be suitably used for the insulator 583b. When silicon nitride or silicon nitride oxide is used for the insulator 583b, the insulator 583b can serve as a blocking layer that inhibits release of oxygen from the insulator 583a. Although the example of the structure where three insulators 583 are stacked is described in this embodiment, the present invention is not limited thereto. For example, the insulating layer 583 may be a single layer. In that case, a barrier insulating film that inhibits diffusion of impurities such as water and hydrogen (e.g., one or both of a hydrogen atom and a hydrogen molecule), typically silicon nitride, can be used for the insulating layer 583.

The insulator 596 and the insulator 583 each include an opening 601 reaching the conductor 542a. The conductor 542b includes an opening 603 reaching the opening 601. That is, the opening 603 includes a region overlapping with the opening 601.

FIG. 22A illustrates, as the components of the transistor 500A, the conductor 542a, the conductor 542b, the metal oxide 533, the conductor 565, the opening 601 and the opening 603. FIG. 22B illustrates a structure example in which the conductor 565 is omitted from the components illustrated in FIG. 22A. In other words, FIG. 22B illustrates the conductor 542a, the conductor 542b, the metal oxide 533, the opening 601, and the opening 603. FIG. 22C illustrates a structure example in which the metal oxide 533 is further omitted from the components illustrated in FIG. 22B. In other words, FIG. 22C illustrates the conductor 542a, the conductor 542b, the opening 601, and the opening 603.

As illustrated in FIG. 22C and FIG. 22D, the conductor 542b includes the opening 603 in a region overlapping with the conductor 542a. As illustrated in FIG. 22C, the conductor 542b can be formed to entirely surround the periphery of the opening 601 in a plan view. It is preferable that the conductor 542b not be provided in the opening 601. In other words, it is preferable that the conductor 542b be not in contact with the side surface of the insulator 583 on the opening 601 side.

FIG. 22A to FIG. 22C illustrate an example in which each of the opening 601 and the opening 603 is circular in a plan view. In the case where the planar shapes of the opening 601 and the opening 603 are circular, the processing accuracy of forming each of the opening 601 and the opening 603 is increased, forming the opening 601 and the opening 603 having minute sizes. Note that in this specification and the like, a circle is not necessarily a perfect circle. For example, the planar shapes of the opening 601 and the opening 603 may be elliptical or a shape including a curve. Alternatively, a polygonal shape may be employed.

FIG. 22D illustrates an example in which the end portion of the conductor 542b on the opening 603 side is aligned with or substantially aligned with the end portion of the insulator 583 on the opening 601 side. In other words, the planar shape of the opening 603 is the same or substantially the same as the planar shape of the opening 601. Note that in this specification and the like, the end portion of the conductor 542b on the opening 603 side refers to the end portion of the bottom surface of the conductor 542b on the opening 603 side. The bottom surface of the conductor 542b refers to the surface on the insulator 583 side. The end portion of the insulator 583 on the opening 601 side refers to the end portion of the top surface of the insulator 583 on the opening 601 side. The top surface of the insulator 583 refers to the surface on the conductor 542b side. The planar shape of the opening 603 refers to the planar shape of the end portion of the bottom surface of the conductor 542b on the opening 603 side. The planar shape of the opening 601 refers to the planar shape of the end portion of the top surface of the insulator 583 on the opening 601 side.

In the case where end portions are aligned or substantially aligned with each other, the end portions can also be said to match or substantially match. In the case where end portions are aligned or substantially aligned with each other and the case where planar shapes are the same or substantially the same, it can be said that outlines of stacked layers at least partly overlap with each other in a plan view. For example, the case of processing the upper layer and the lower layer with use of the same mask pattern or mask patterns that are partly the same is included. Note that, in some cases, the outlines do not completely overlap with each other and the upper layer is positioned inside the lower layer or the upper layer is positioned outside the lower layer; such cases are also represented by the expression “end portions substantially match” or the expression “planar shapes are substantially the same”.

The opening 601 can be formed using a resist mask used for the formation of the opening 603, for example. Specifically, first, the insulator 596 is formed over the conductor 542a and the insulator 595, the insulator 583 is formed over the insulator 596, a conductive film to be the conductor 542b is formed over the insulator 583, and a resist mask is formed over the conductive film. Then, the opening 603 is formed in the conductive film using the resist mask and then the opening 601 is formed in the insulator 596 and the insulator 583 using the resist mask, whereby the end portion of the opening 601 and the end portion of the opening 603 can be aligned or substantially aligned with each other. With such a structure, the process can be simplified.

The metal oxide 533 is provided to include a region positioned inside the opening 601 and the opening 603 to cover the opening 601 and the opening 603. The metal oxide 533 has a shape along the top surface and the side surface of the conductor 542b, the side surface of the insulator 583, the side surface of the insulator 596 and the top surface of the conductor 542a. The metal oxide 533 includes, for example, a region in contact with the top surface and the side surface of the conductor 542b, the side surface of the insulator 583, and the top surface of the conductor 542a.

The metal oxide 533 preferably covers the end portion of the conductor 542b on the opening 603 side. For example, FIG. 22D illustrates a structure in which the end portion of the metal oxide 533 is positioned over the conductor 542b. The end portion of the metal oxide 533 can also be said to be in contact with the top surface of the conductor 542b.

Although the metal oxide 533 has a single-layer structure in FIG. 22D, for example, one embodiment of the present invention is not limited thereto. The metal oxide 533 may have a stacked-layer structure of two or more layers.

The insulator 555 functioning as the gate insulating layer of the transistor 500A is provided to cover the opening 601 and the opening 603 and include a region positioned in the opening 601 and the opening 603. The insulator 555 is provided over the metal oxide 533, over the conductor 542b, and over the insulator 583. The insulator 555 can include a region in contact with the top surface and the side surface of the metal oxide 533, the top surface and the side surface of the conductor 542b, the top surface of the insulator 583, and the top surface of the insulator 596. The insulator 555 has a shape along the top surface of the insulator 596, the top surface of the insulator 583, the top surface and the side surface of the conductor 542b, and the top surface and the side surface of the metal oxide 533.

The conductor 565 functioning as the gate electrode of the transistor 500A can be provided over the insulator 555 and can include a region in contact with the top surface of the insulator 555. The conductor 565 includes a region overlapping with the metal oxide 533 with the insulator 555 therebetween. The conductor 565 has a shape along the shape of the top surface of the insulator 555.

For example, as illustrated in FIG. 22D, the conductor 565 includes a region overlapping with the metal oxide 533 with the insulator 555 therebetween in the opening 601 and the opening 603. In the example illustrated in FIG. 22D, the conductor 565 includes a region overlapping with the conductor 542a and the conductor 542b with the insulator 555 and the metal oxide 533 therebetween. The conductor 565 covers the entire metal oxide 533. With such a structure, a gate electric field can be applied to the entire metal oxide 533, which allows the transistor 500A to have better electrical characteristics, for example, the on-state current of the transistor can be increased.

The transistor 500A is what is called a top-gate transistor including a gate electrode above the metal oxide 533. Furthermore, since the bottom surface of the metal oxide 533 includes a region in contact with the source electrode and the drain electrode, the transistor 500A can be referred to as a TGBC (Top Gate Bottom Contact) transistor.

The transistor 500A is a transistor in which at least part of a semiconductor layer including a channel formation region is provided along a side surface of the insulating layer in an opening formed in the insulating layer. In this specification and the like, such a transistor is referred to as a vertical transistor in some cases.

Note that in a vertical transistor, the source electrode and the drain electrode are positioned at different levels, which causes current flow in the height direction (the vertical direction) in the channel formation region of the semiconductor layer. In other words, the channel length direction can be regarded as having a component of the height direction (the vertical direction). Thus, the above-described vertical transistor can also be referred to as a VFET (Vertical Field-Effect Transistor), a vertical-channel transistor, or a vertical-channel-type transistor, for example.

In a vertical transistor, the source region, the channel formation region, and the drain region can at least partly overlap with one another in the top view, enabling a smaller occupied area (footprint). Such a transistor enables reduced channel length and increased channel width, reducing on-state resistance (increasing on-state current).

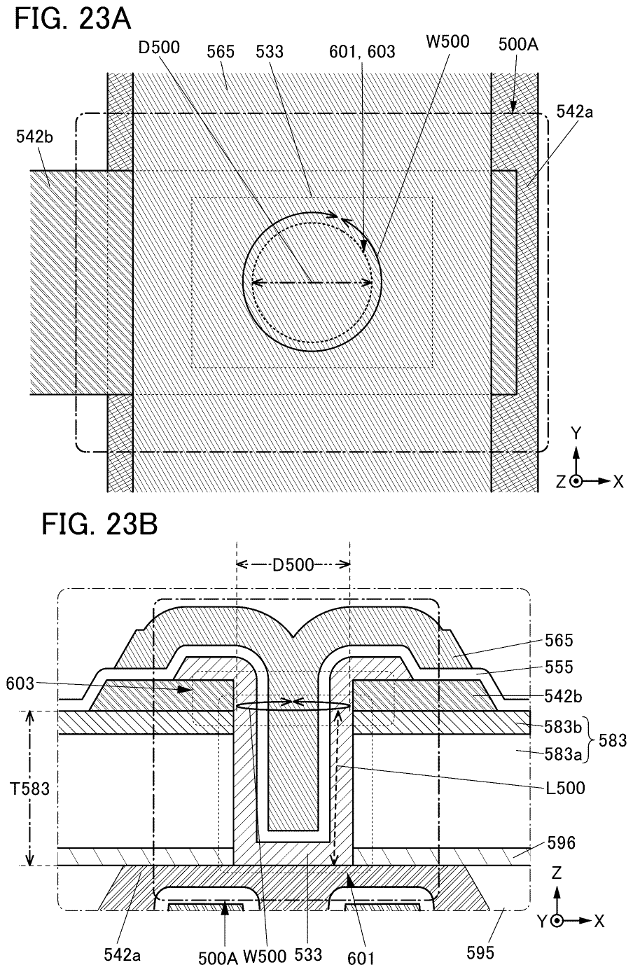

Here, the channel length and channel width of the transistor 500A are described with reference to FIG. 23A and FIG. 23B. FIG. 23A is an enlarged view of the plan view of FIG. 22A illustrating the structure example of the transistor 500A and the vicinity thereof. FIG. 23B is an enlarged view of the cross-sectional view of FIG. 22D illustrating the structure example of the transistor 500A and the vicinity thereof.

In the metal oxide 533, a region in contact with the conductor 542a functions as one of the source region and the drain region, a region in contact with the conductor 542b functions as the other of the source region and the drain region, and a region between the source region and the drain region functions as the channel formation region.

The channel length of the transistor 500A is a distance between the source region and the drain region. In FIG. 23B, a channel length L500 of the transistor 500A is indicated by a dashed double-headed arrow. In the cross-sectional view, the channel length L500 is a distance between the end portion of the region where the metal oxide 533 is in contact with the conductor 542a and the end portion of the region where the metal oxide 533 is in contact with the conductor 542b.

Here, the channel length L500 of the transistor 500A corresponds to the length of the side surface of the insulator 583 on the opening 601 side when seen from the XZ plane. That is, the channel length L500 is determined by a thickness T583 of the insulator 596 and the insulator 583, and is not affected by the performance of a light-exposure apparatus used for manufacturing the transistor. Thus, the channel length L500 can be a value smaller than that of the resolution limit of the light-exposure apparatus, which enables the transistor to have a minute size. For example, the channel length L500 is preferably larger than or equal to 0.0010 μm, that is, larger than or equal to 1 nm, preferably 0.010 μm and smaller than 3.0 μm, still further preferably larger than or equal to 0.050 μm and smaller than 3.0 μm, yet still further preferably larger than or equal to 0.10 μm and smaller than 3.0 μm, yet still further preferably larger than or equal to 0.15 μm and smaller than 3.0 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 23B, the thickness T583 of the insulator 583 is indicated by a dashed-dotted double-headed arrow.

When the transistor 500A is applied to a transistor included in the memory cell MC, the memory cell MC can be miniaturized. This can increase the memory density, so that the semiconductor device can have high memory capacity. Furthermore, when the channel length L500 is reduced, the on-state current of the transistor 500A can be increased, so that the memory cell MC can be driven at high speed.

The channel length L500 can be controlled by adjustment of the thickness T583 of the insulator 596 and the insulator 583.

The thickness T583 of the insulator 596 and the insulator 583 is preferably larger than or equal to 0.0010 μm, that is larger than or equal to 1 nm, further preferably larger than or equal to 0.010μm and less than 3.0 μm, still further preferably larger than or equal to 0.050 μm and less than 3.0 μm, yet still further preferably greater than or equal to 0.10 μm and less than 3.0 μm, yet still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

Although FIG. 23B illustrates the structure in which the side surfaces of the insulator 596 and the insulator 583 on the opening 601 side are linear in the cross-sectional view, one embodiment of the present invention is not limited thereto. In the cross-sectional view, the side surfaces of the insulator 596 and the insulator 583 on the opening 601 side may be curved, or the side surfaces may include both a linear region and a curved region.

The channel width of the transistor 500A is a width of the source region or a width of the drain region in the direction orthogonal to the channel length direction. In other words, the channel width is the width of the region where the metal oxide 533 is in contact with the conductor 542a or the width of the region where the metal oxide 533 is in contact with the conductor 542b in the direction orthogonal to the channel length direction. Here, the channel width of the transistor 500A is described as the width of the region where the metal oxide 533 and the conductor 542b are in contact with each other in the direction orthogonal to the channel length direction. In FIG. 23A and FIG. 23B, a channel width W500 of the transistor 500A is indicated by a solid double-headed arrow. In the plan view, the channel width W500 is the length of the end portion of the bottom surface of the conductor 542b on the opening 603 side.

The channel width W500 is determined by the planar shape of the opening 603. In FIG. 23A and FIG. 23B, a width D500 of the opening 603 is indicated by a dashed-two dotted double-headed arrow. In the plan view, the width D500 refers to the short side of the smallest rectangle that is circumscribed around the opening 603. In the case where the opening 603 is formed by a photolithography method, the width D500 of the opening 603 is larger than or equal to the resolution limit of a light-exposure apparatus. For example, the width D500 is preferably larger than or equal to 0.20 μm and smaller than 5.0 μm, further preferably larger than or equal to 0.20 μm and smaller than 4.5 μm, still further preferably larger than or equal to 0.20 μm and smaller than 4.0 μm, yet still further preferably larger than or equal to 0.20 μm and smaller than 3.5 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. Note that when the planar shape of the opening 603 is circular, the width D500 corresponds to the diameter of the opening 603, and the channel width W500 can be equal to the length of the periphery of the opening 603 in a plan view and calculated to be “D500×π”.

Since the size of the transistor 500A is small, by applying the transistor 500A to the element layer 700, memory density can be increased, so that a semiconductor device including the memory unit with high memory capacity can be provided. Since the operation speed of the transistor 500A is high, by applying the transistor 500A to a semiconductor device, a semiconductor device with high driving speed can be provided. Since the electrical characteristics of the transistor 500A are stable, by applying the transistor 500A to a semiconductor device, a semiconductor device with high reliability can be provided. Since the amount of the off-state current of the transistor 500A is small, by applying the transistor 500A to a semiconductor device, a semiconductor device with low power consumption can be provided.

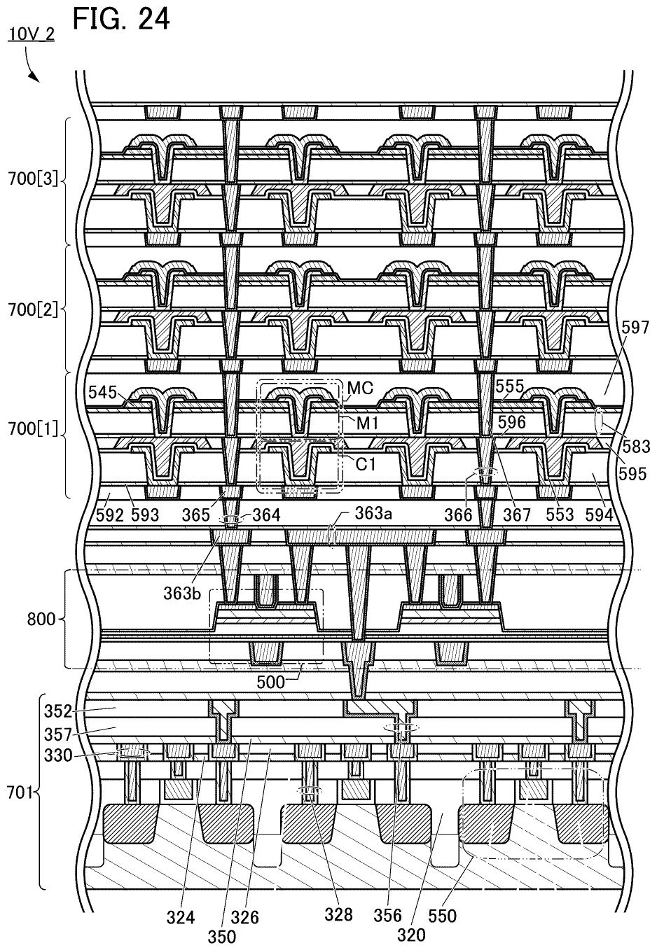

The transistor 500A can also be applied to a transistor included in a circuit different from the memory cell MC, for example. It is possible to apply another transistor structure which combines with, for example, the element layer 800 including the transistor 500 which is described in FIG. 17 as described in the semiconductor device 10V_2 illustrated in FIG. 24. With this structure, transistors having different transistor characteristics can be stacked, so that circuit arrangement depending on switching characteristics can be performed.

This embodiment can be implemented in combination with the other embodiments described in this specification as appropriate.

### Embodiment 3

This embodiment describes an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device according to one embodiment of the present invention are effective in achieving high performance, e.g., reducing power consumption.

### [Electronic Component]

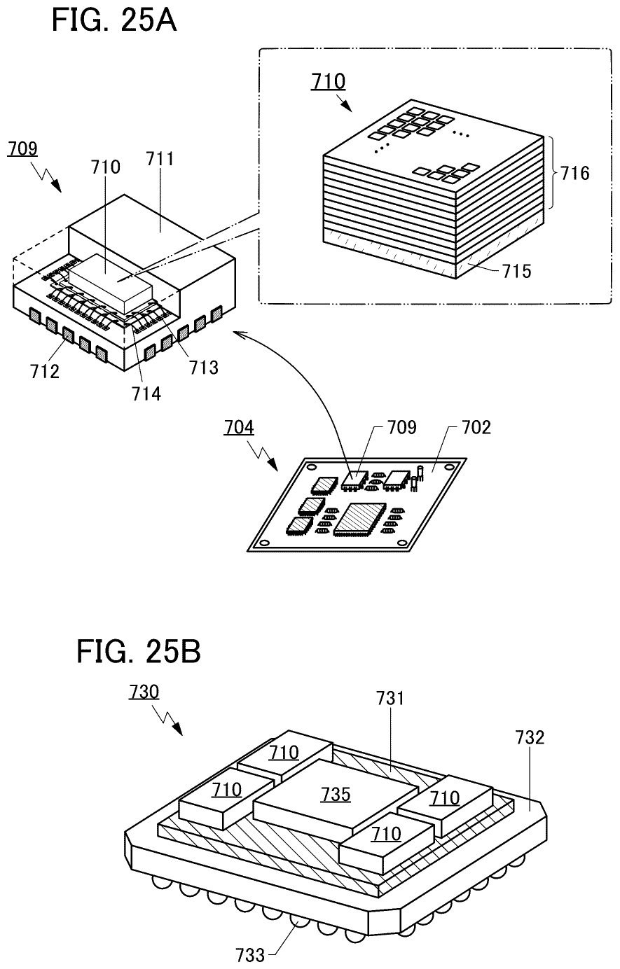

FIG. 25A illustrates a perspective view of a substrate (a mount board 704) on which an electronic component 709 is mounted. The electronic component 709 illustrated in FIG. 25A includes a semiconductor device 710 in a mold 711. FIG. 25A omits illustrations of some parts to show the inside of the electronic component 709. The electronic component 709 includes lands 712 outside the mold 711. The land 712 is electrically connected to an electrode pad 713, and the electrode pad 713 is electrically connected to the semiconductor device 710 via a wire 714. The electronic component 709 is mounted on a printed circuit board 702, for example. A plurality of such electronic components are combined and electrically connected on the printed circuit board 702, so that the mount board 704 is completed.

In addition, the semiconductor device 710 includes a driver circuit layer 715 and a memory layer 716. Note that the memory layer 716 has a configuration where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the memory layer 716 enables, for example, what is called an on-chip memory configuration where a memory is directly formed on a processor. The on-chip memory configuration allows an interface portion between the processor and the memory to operate at high speed.

In addition, with the on-chip memory configuration, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

Furthermore, it is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

Moreover, the semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 25B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is referred to as a “redistribution substrate” or an “intermediate substrate” in some cases. A through electrode is provided in the interposer 731 and the integrated circuit and the package substrate 732 are electrically connected through the through electrode in some cases. Moreover, in a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity, and poor connection between the silicon interposer and an integrated circuit provided on the silicon interposer does not easily occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

In addition, a heat sink (a radiator plate) may be provided to overlap the electronic component 730. In the case where a heat sink is provided, the heights of integrated circuits provided on the interposer 731 are preferably aligned with each other. For example, in the electronic component 730 described in this embodiment, the heights of the semiconductor devices 710 and the semiconductor device 735 are preferably aligned with each other.

Electrodes 733 may be provided on a bottom portion of the package substrate 732 to mount the electronic component 730 on another substrate. FIG. 25B illustrates an example where the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

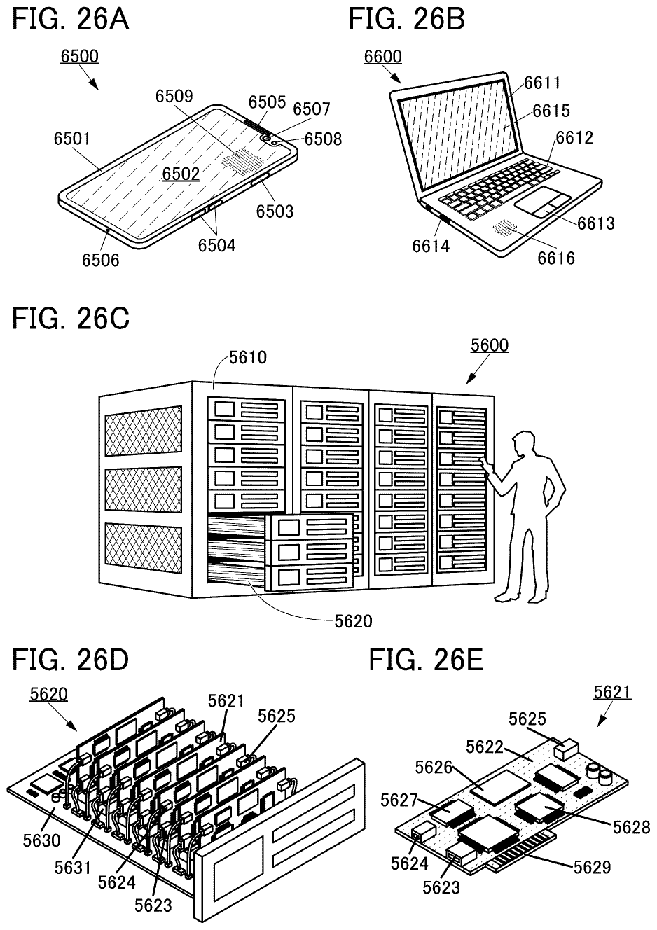

Next, FIG. 26A illustrates a perspective view of an electronic device 6500. The electronic device 6500 illustrated in FIG. 26A is a portable information terminal that can be used as a smartphone. The electronic device 6500 includes a housing 6501, a display unit 6502, a power button 6503, buttons 6504, a speaker 6505, a microphone 6506, a camera 6507, a light source 6508, a control device 6509, and the like. Note that the control device 6509 includes one or more selected from a CPU, a GPU, and a semiconductor device, for example. The semiconductor device according to one embodiment of the present invention can be applied to the display unit 6502, the control device 6509, or the like.

An electronic device 6600 illustrated in FIG. 26B is an information terminal that can be used as a laptop personal computer. The electronic device 6600 includes a housing 6611, a keyboard 6612, a pointing device 6613, an external connection port 6614, a display unit 6615, a control device 6616, and the like. Note that the control device 6616 includes one or more selected from a CPU, a GPU, and a semiconductor device, for example. The semiconductor device according to one embodiment of the present invention can be applied to the display unit 6615, the control device 6616, or the like. Note that the semiconductor device according to one embodiment of the present invention is suitably used for each of the control device 6509 and the control device 6616 because power consumption can be reduced.

### [Large Computer]

Next, FIG. 26C illustrates a perspective view of a large computer 5600. In the large computer 5600 illustrated in FIG. 26C, a plurality of rack mount computers 5620 are stored in a rack 5610. Note that the large computer 5600 may also be referred to as a supercomputer.

The computer 5620 can have a configuration in a perspective view illustrated in FIG. 26D, for example. In FIG. 26D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, a semiconductor device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a semiconductor device or the like. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device according to one embodiment of the present invention can be suitably used for space equipment such as equipment that processes and stores information.

The semiconductor device according to one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space.

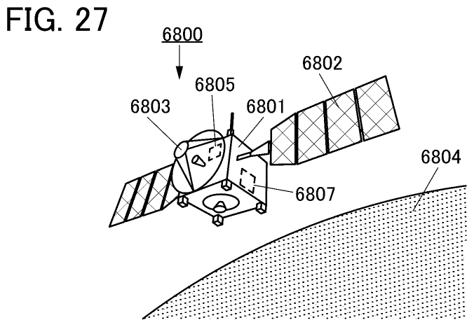

FIG. 27 illustrates an artificial satellite 6800 as an example of space equipment. The artificial satellite 6800 includes a body 6801, solar panels 6802, an antenna 6803, a secondary battery 6805, and a control device 6807. Note that FIG. 27 illustrates a planet 6804 in outer space, for example. Note that outer space refers to, for example, space at an altitude greater than or equal to 100 km, and outer space described in this specification may include the thermosphere, the mesosphere, and the stratosphere.

In addition, although not illustrated in FIG. 27, a battery management system (also referred to as a BMS) or a battery control circuit may be provided in the secondary battery 6805. An OS transistor is suitably used in the battery management system or the battery control circuit because low power consumption and high reliability even in outer space are achieved.

Furthermore, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

In addition, the control device 6807 has a function of controlling the artificial satellite 6800. The control device 6807 is formed using one or more selected from a CPU, a GPU, and a semiconductor device, for example. Note that the semiconductor device according to one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

Alternatively, the artificial satellite 6800 can include a sensor. For example, when the artificial satellite 6800 includes a visible light sensor, the artificial satellite 6800 can have a function of detecting sunlight reflected by a ground-based object. Alternatively, when the artificial satellite 6800 includes a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is illustrated as an example of space equipment in this embodiment, the present invention is not limited thereto. The semiconductor device according to one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device according to one embodiment of the present invention can be suitably applied to, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device according to one embodiment of the present invention for a storage system applied to a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device according to one embodiment of the present invention can achieve a data center that stably operates even in a high-temperature environment. Thus, the reliability of the data center can be increased.

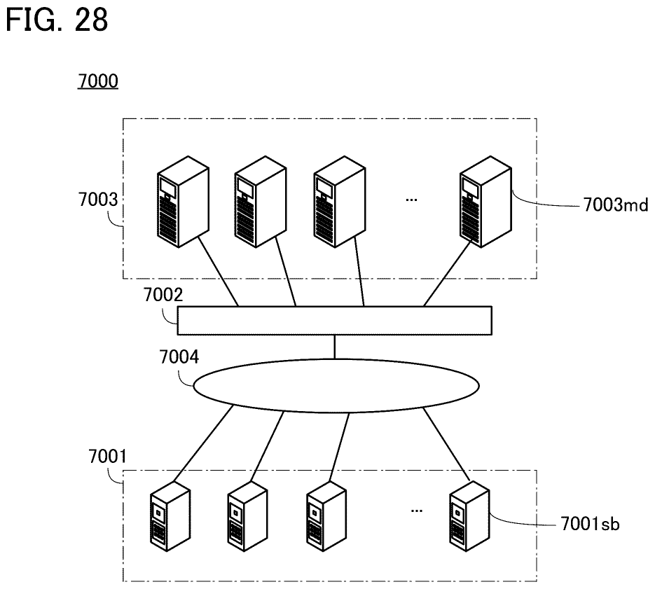

FIG. 28 illustrates a storage system applicable to a data center. A storage system 7000 illustrated in FIG. 28 includes a plurality of servers 7001sb as a host 7001. A storage 7003 includes a plurality of semiconductor devices 7003md. In the illustrated example, the host 7001 and the storage 7003 are connected to each other through a storage area network 7004 and a storage control circuit 7002.

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the application of the semiconductor device according to one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device according to one embodiment of the present invention. Furthermore, the semiconductor device according to one embodiment of the present invention has low power consumption and thus is effective as a global warming countermeasure.

The configuration, structure, method, and the like described in this embodiment can be used in combination as appropriate with the configurations, structures, methods, and the like described in the other embodiments and the like.

### Supplementary Notes on Description in this Specification and the Like

The description of the above embodiments and each configuration in the embodiments are noted below.

One embodiment of the present invention can be constituted by combining, as appropriate, the configuration described in each embodiment with the configurations described in the other embodiments. In addition, in the case where a plurality of configuration examples are described in one embodiment, the configuration examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an ON state) or a non-conduction state (an OFF state). Alternatively, a switch has a function of selecting and changing a current path.

In this specification and the like, a channel length of a planar transistor refers to, for example, the distance between a source and a drain in a region where a semiconductor (or a portion where current flows in a semiconductor when a transistor is in an ON state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an ON state) and a gate electrode overlap each other or a region where a channel is formed.

In this specification and the like, a node can be referred to as a terminal, a wiring, an electrode, a conductive layer, a conductor, an impurity region, or the like depending on a circuit configuration, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### Reference Numerals

10: semiconductor device, 20: element layer, 21: arithmetic unit, 30: element layer, 32: functional circuit unit, 33: memory unit, 34: memory cell, 35: transistor, 36: capacitor, 100: arithmetic processing system, 210: memory unit, 211: instruction decoder, 212: branch prediction unit, 213: store unit, 214: arithmetic logic unit, 215: floating-point arithmetic unit, 216: general-purpose register, 220: memory unit, 221: L1 cache, 222: L2 cache, 223: L3 cache, 230: memory unit, 240: memory unit.

1. A semiconductor device comprising:
a first element layer; and
a plurality of second element layers,
wherein the plurality of second element layers are provided over the first element layer,
wherein an arithmetic unit is provided in the first element layer,
wherein a memory unit is provided in each of the plurality of second element layers;
wherein the arithmetic unit comprises a first transistor comprising a first semiconductor layer comprising silicon in a channel formation region,
wherein the memory unit comprises a second transistor comprising a second semiconductor layer comprising an oxide semiconductor in a channel formation region, and
wherein the memory unit is configured to be used as a cache memory of the arithmetic unit.

2. A semiconductor device comprising:
a first element layer; and
a plurality of second element layers,
wherein the plurality of second element layers are provided over the first element layer,
wherein an arithmetic unit is provided in the first element layer,
wherein a memory unit is provided in each of the plurality of second element layers,
wherein the arithmetic unit comprises a first transistor comprising a first semiconductor layer comprising silicon in a channel formation region,
wherein the memory unit comprises a second transistor comprising a second semiconductor layer comprising an oxide semiconductor in a channel formation region,
wherein the arithmetic unit comprises an instruction decoder,
wherein the memory unit in at least one of the plurality of second element layers comprises an instruction cache, and
wherein the instruction cache is provided in a region included in the second element layer above the instruction decoder provided in the first element layer.

3. The semiconductor device according to claim 1,
wherein the oxide semiconductor comprises at least In.

4.

4. The semiconductor device according to claim 1,
wherein the second transistor is a vertical transistor.

5. The semiconductor device according to claim 1,
wherein the arithmetic unit included in the first element layer and the memory unit included in each of the plurality of second element layers are electrically connected to each other via a through electrode provided in each of the plurality of second element layers.

6. The semiconductor device according to claim 1,
wherein the arithmetic unit included in the first element layer and the memory unit included in each of the plurality of second element layers are electrically connected to each other through a wiring layer included in the first element layer and a wiring layer included in each of the plurality of second element layers.

7. The semiconductor device according to claim 1,
wherein the arithmetic unit included in the first element layer comprises a flip-flop,
wherein each of the plurality of second element layers comprises a backup circuit electrically connected to the flip-flop,
wherein the backup circuit is configured to retain a data signal written to the flip-flop, and
wherein a region where the backup circuit is provided overlaps with a region where the flip-flop is provided.

8. The semiconductor device according to claim 2,
wherein the oxide semiconductor comprises at least In.

9. The semiconductor device according to claim 2,
wherein the second transistor is a vertical transistor.

10. The semiconductor device according to claim 2,
wherein the arithmetic unit included in the first element layer and the memory unit included in each of the plurality of second element layers are electrically connected to each other via a through electrode provided in each of the plurality of second element layers.

11. The semiconductor device according to claim 2,
wherein the arithmetic unit included in the first element layer and the memory unit included in each of the plurality of second element layers are electrically connected to each other through a wiring layer included in the first element layer and a wiring layer included in each of the plurality of second element layers.

12. The semiconductor device according to claim 2,
wherein the arithmetic unit included in the first element layer comprises a flip-flop,
wherein each of the plurality of second element layers comprises a backup circuit electrically connected to the flip-flop,
wherein the backup circuit is configured to retain a data signal written to the flip-flop, and
wherein a region where the backup circuit is provided overlaps with a region where the flip-flop is provided.
